(19) United States
(12) Patent Application Publication
(10) Pub. No.: US 2026/0101748 A1
(43) Pub. Date: Apr. 9, 2026

(54) SEMICONDUCTOR DEVICE

(71) Applicant: Samsung Electronics Co., Ltd., Suwon-si (KR)

(72) Inventors: Yongjun Kim, Suwon-si (KR); Junil Lee, Suwon-si (KR); Sangwan Nam, Suwon-si (KR)

(21) Appl. No.: 19/323,460

(22) Filed: Sep. 9, 2025

(30) Foreign Application Priority Data
Oct. 8, 2024 (KR) 10-2024-0136376

(51) Int. Cl. H01L 23/522; H01L 23/528; H01L 25/18; H10B 80/00; H10D 80/30

(52) U.S. Cl. CPC H10W 20/496; H10W 20/42; H10W 20/435; H10B 80/00; H10D 80/30; H10W 90/00

(57) ABSTRACT

A semiconductor device includes: a substrate including a first region and a second region; a first interconnection structure on the first region; and a capacitor structure on the second region, and the capacitor structure includes: a first electrode structure including first portions; a second electrode structure including second portions alternately arranged with the first portions; and a dielectric capacitor structure disposed between the first portions and the second portions, and the first interconnection structure includes: a first peripheral interconnection line; a first peripheral contact plug on the first peripheral interconnection line; and a first peripheral dielectric structure on a side surface of the first peripheral interconnection line and a side surface of the first peripheral contact plug, the dielectric capacitor structure may include a first dielectric material, and the first peripheral dielectric structure may include a second dielectric material.

### CROSS-REFERENCE TO RELATED APPLICATION(S)

This application claims benefit of priority to Korean Patent Application No. 10-2024-0136376 filed on Oct. 8, 2024, in the Korean Intellectual Property Office, the disclosure of which is incorporated herein by reference in its entirety.

### BACKGROUND

In a data storage system requiring data storage, a semiconductor device capable of storing a large amount of data is required. Accordingly, a method of increasing the data storage capacity of a semiconductor device has been researched. For example, as one of the methods of increasing the data storage capacity of a semiconductor device, a semiconductor device including memory cells arranged three-dimensionally, instead of memory cells arranged two-dimensionally, has been proposed.

### SUMMARY

In general, the present disclosure is directed toward a semiconductor device having improved electrical characteristics.

According to some implementations, the present disclosure is directed to a semiconductor device that includes: a first semiconductor structure including a substrate having a first region and a second region, a first interconnection structure on the first region of the substrate, and a capacitor structure on the second region of the substrate; and a second semiconductor structure including memory cells overlapping the first semiconductor structure in a vertical direction, and the first interconnection structure may include: at least one peripheral interconnection line; at least one peripheral contact plug disposed on a different level from a level of the at least one peripheral interconnection line; and a first peripheral dielectric structure on a side surface of the at least one peripheral interconnection line and a side surface of the at least one peripheral contact plug, and the capacitor structure may include: a first electrode structure including first portions spaced apart from each other in a first direction and extending in a second direction and the vertical direction; a second electrode structure including second portions alternately arranged with the first portions in the first direction and extending in the second direction and the vertical direction; and a dielectric capacitor structure between the first portions of the first electrode structure and the second portions of the second electrode structure, and the first direction may be a direction, parallel to an upper surface of the substrate, the second direction may be parallel to the upper surface of the substrate and intersect the first direction, the vertical direction is perpendicular to the upper surface of the substrate and intersects the first direction and the second direction, each of the first portions may include a first lower electrode and a first intermediate electrode overlapping the first lower electrode in the vertical direction, each of the second portions may include a second lower electrode and a second intermediate electrode overlapping the second lower electrode in the vertical direction, the first and second lower electrodes may be disposed on a same level as a first peripheral interconnection line of the at least one peripheral interconnection line, the first and second intermediate electrodes may be disposed on a same level as a first peripheral contact plug of the at least one peripheral contact plug, the dielectric capacitor structure may include a first dielectric material having a first dielectric constant, and the first peripheral dielectric structure may include a second dielectric material having a second dielectric constant, lower than the first dielectric constant.

According to some implementations, the present disclosure is directed to a semiconductor device that includes: a substrate including a first region and a second region surrounded by the first region; a first interconnection structure on the first region of the substrate; and a capacitor structure on the second region of the substrate, and the capacitor structure may include: a first electrode structure including first portions spaced apart from each other in a first direction and extending in a second direction and a vertical direction; a second electrode structure including second portions alternately arranged with the first portions in the first direction and extending in the second direction and the vertical direction; a dielectric capacitor structure between the first portions of the first electrode structure and the second portions of the second electrode structure, and the first interconnection structure may include: a first peripheral interconnection line extending in the second direction; a first peripheral contact plug on the first peripheral interconnection line; and a first peripheral dielectric structure on a side surface of the first peripheral interconnection line and a side surface of the first peripheral contact plug, and the first direction may be a direction parallel to an upper surface of the substrate, the second direction may be parallel to the upper surface of the substrate and intersect the first direction, and the vertical direction may be perpendicular to the upper surface of the substrate and intersects the first direction and the second direction, the first peripheral dielectric structure may surround a side surface of the dielectric capacitor structure, the dielectric capacitor structure may include a first dielectric material having a first dielectric constant, and the first peripheral dielectric structure may include a second dielectric material having a second dielectric constant, lower than the first dielectric constant.

According to some implementations, the present disclosure is directed to a semiconductor device that includes: a substrate; a first circuit element on the substrate; contact plugs connected to the first circuit element; a first insulating layer on side surfaces of the contact plugs; and a capacitor structure on the first insulating layer, and the capacitor structure may include: a first electrode structure including first portions spaced apart from each other in a first direction, parallel to an upper surface of the substrate, and extending in a second direction, intersecting the first direction and extending in a vertical direction intersecting the first direction and the second direction; a second electrode structure including second portions alternately arranged with the first portions in the first direction and extending in the second direction and in the vertical direction; and a dielectric capacitor structure between the first portions of the first electrode structure and the second portions of the second electrode structure, and the dielectric capacitor structure may include a first dielectric material having a first dielectric constant, and the first insulating layer may include a second dielectric material having a second dielectric constant, lower than the first dielectric constant.

According to some implementations, the present disclosure is directed to a semiconductor device that includes an interconnection structure and a capacitor structure disposed on the same level as the interconnection structure, and a dielectric constant of a capacitor dielectric layer included in the capacitor structure may have a dielectric constant higher than a dielectric constant of an insulating layer of the interconnection structure. Accordingly, a capacitor structure having high capacitance may be secured while the capacitance between interconnection lines may be minimized, thereby providing a semiconductor device having improved electrical characteristics.

### BRIEF DESCRIPTION OF DRAWINGS

Example implementations will be more clearly understood from the following detailed description, taken in conjunction with the accompanying drawings.

FIG. 1A is a schematic block diagram of an example of a semiconductor device according to some implementations.

FIG. 1B is a circuit diagram illustrating an example of a charge pump circuit included in a voltage generator of a semiconductor device according to some implementations.

FIG. 2A is a schematic plan view of an example of a semiconductor device according to some implementations.

FIG. 2B is a cross-sectional view taken along line I-I′ of the semiconductor device of FIG. 2A according to some implementations.

FIG. 2C is a cross-sectional view taken along line II-II′ of the semiconductor device of FIG. 2A according to some implementations.

FIG. 3A is a perspective view illustrating examples of first electrode structures and second electrode structures of a capacitor structure of the semiconductor device of FIG. 2A some implementations.

FIG. 3B is a perspective view illustrating examples of first electrode structures and second electrode structures of a capacitor structure of the semiconductor device of FIG. 2A some implementations.

FIG. 4 is a schematic perspective view illustrating an example of a peripheral circuit region of a semiconductor device some implementations.

FIG. 5A is a cross-sectional view illustrating an example of a peripheral circuit region of a semiconductor device some implementations.

FIG. 5B is a cross-sectional view illustrating an example of a peripheral circuit region of a semiconductor device some implementations.

FIG. 6 is a cross-sectional view taken along line I-I′ of the semiconductor device of FIG. 2A according to some implementations.

FIGS. 7A to 7K are views illustrating an example of a method of manufacturing a semiconductor device according to some implementations.

FIGS. 8A to 8E are views illustrating an example of a method of manufacturing a semiconductor device according to some implementations.

FIG. 9 is a view schematically illustrating an example of a data storage system including a semiconductor device according to some implementations.

### DETAILED DESCRIPTION

Hereinafter, example implementations will be explained in detail with reference to the accompanying drawings. The same reference numerals are used for the same components in the drawings, and duplicate descriptions of the same components are omitted.

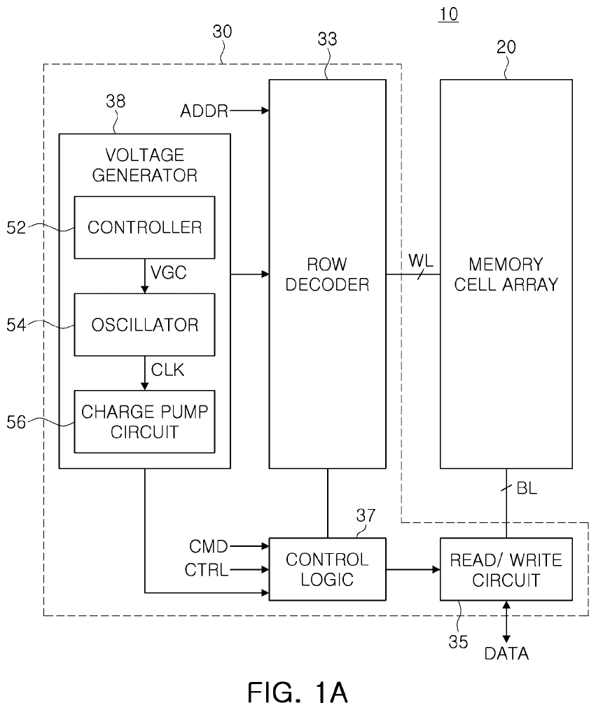

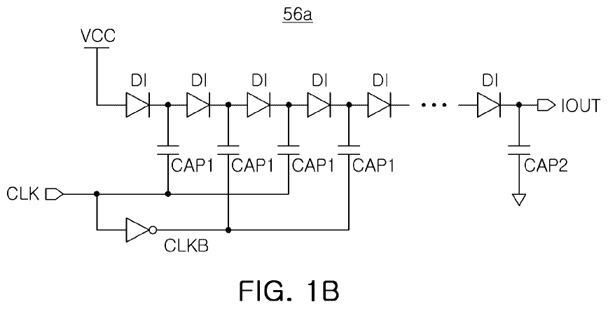

FIG. 1A is a schematic block diagram of an example of a semiconductor device according to some implementations. In FIG. 1A, a semiconductor device 10 may include a memory cell array 20 and a peripheral circuit 30. The semiconductor device 10 may be a memory device, and may be, for example, a nonvolatile memory, such as a flash memory, or a volatile memory, such as a dynamic random access memory (DRAM), a static random access memory (SRAM), or the like.

The memory cell array 20 may include a plurality of memory cells. The plurality of memory cells may be connected to a row decoder 33 through a plurality of word lines WL and may be connected to a read/write circuit 35 through bit lines BL. In an example, a plurality of memory cells arranged along the same row may be connected to the same word line WL, and a plurality of memory cells arranged along the same column may be connected to the same bit line BL. In some implementations, a plurality of memory blocks may be included, and each of the memory blocks may include a plurality of memory cells.

The peripheral circuit 30 may receive an address ADDR, a command CMD, and a control signal CTRL from the outside of the semiconductor device 10, and may transmit and receive data DATA with an external device of the semiconductor device 10. The peripheral circuit 30 may include the row decoder 33, the read/write circuit 35, a control logic 37, and a voltage generator 38 generating various voltages necessary for operation. According to some implementations, the peripheral circuit 30 may further include various sub-circuits, such as an input/output circuit, an error correction circuit for correcting errors in data DATA read from a memory cell array 20, or the like.

The control logic 37 may be connected to the row decoder 33, the voltage generator 38, and the input/output circuit. The control logic 37 may control an overall operation of the semiconductor device 10. The control logic 37 may generate various internal control signals used in the semiconductor device 10 in response to the control signal CTRL. For example, the control logic 37 may control voltage levels provided to the word lines WL and the bit lines BL when performing a memory operation such as a program operation or an erase operation.

The row decoder 33 may select some of a plurality of memory cells in response to the address ADDR and may select at least one word line WL. The row decoder 33 may transmit a voltage for performing a memory operation to the selected word line WL.

The read/write circuit 35 may be connected to the memory cell array 20 through the bit lines BL. The read/write circuit 35 may include a writer driver or a sense amplifier. Specifically, during a program operation, the read/write circuit 35 may operate as the write driver to apply voltage according to data DATA to be stored in the memory cell array 20 to the bit lines BL. Meanwhile, during a read operation, the read/write circuit 35 may operate as the sense amplifier to sense data DATA stored in the memory cell array 20.

The voltage generator 38 may include a controller 52, an oscillator 54, and a charge pump 56.

The charge pump 56 may include a plurality of charge pumps, and each of the plurality of charge pumps may include at least one switching element and at least one pumping capacitor. The charge pump 56 may provide current through the row decoder 33 to apply an operating voltage to the word line WL of the memory cell array.

The controller 52 may control an operation of the oscillator 54. For example, the controller 52 may determine one selected charge pump, among the plurality of charge pumps, based on at least one of the Process, Voltage, Temperature (PVT) information of the semiconductor device 10 and a target level of a power voltage to be supplied. The controller 52 may deactivate the remaining charge pumps excluding the selected charge pump.

The oscillator 54 may output a clock signal CLK. The oscillator 54 may operate in response to a control signal VGC from the controller 52. For example, the oscillator 54 may output the clock signal CLK to at least some of the charge pumps, among the plurality of charge pumps, in response to the control signal VGC transmitted by the controller 52.

FIG. 1B is a circuit diagram illustrating an example of a charge pump circuit included in a voltage generator of a semiconductor device according to some implementations. In FIG. 1B, a charge pump circuit 56a may include a plurality of diodes DI, a plurality of pumping capacitors CAP1, and an output capacitor CAP2. The plurality of diodes DI may be connected to each other in series, and a plurality of pumping capacitors CAP1 may be connected to a node between the plurality of diodes DI. A first diode may receive a power supply voltage VCC having a predetermined level, and a last diode may output an output current IOUT to an output node.

Each of the plurality of pumping capacitors CAP1 may be charged or discharged by the clock signal CLK or a complementary clock signal CLKB phase-shifted to have an opposite phase to the clock signal CLK by an inverter INV. For example, odd-numbered pumping capacitors CAP1 may be charged or discharged by the clock signal CLK, and even-numbered pumping capacitors CAP1 may be charged or discharged by the complementary clock signal CLKB.

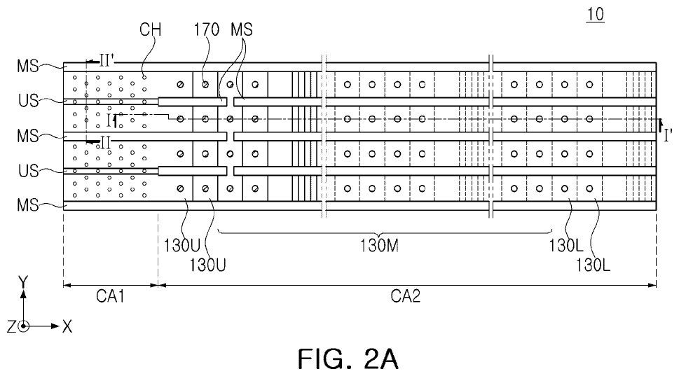

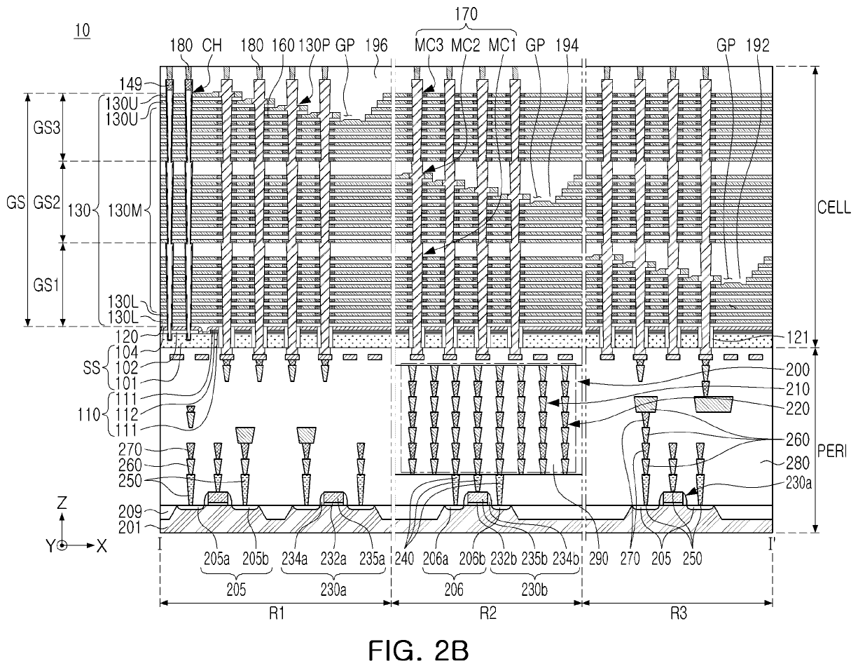

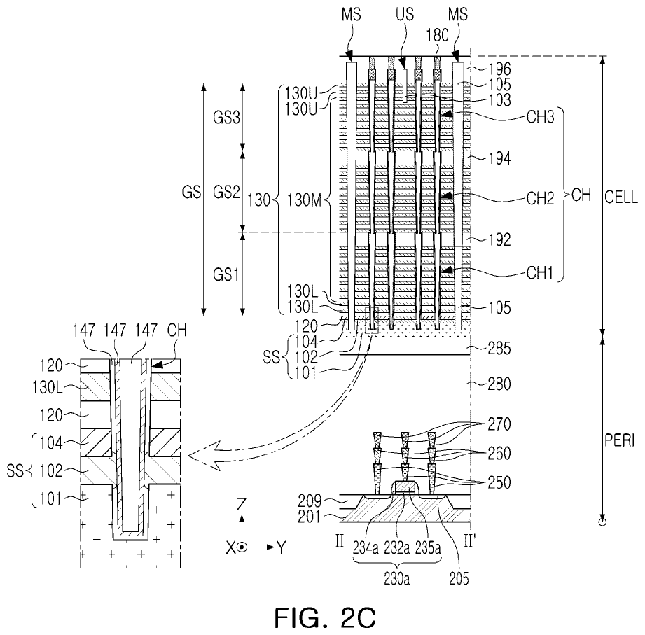

FIG. 2A is a schematic plan view of an example of a semiconductor device according to some implementations. FIG. 2B is a cross-sectional view taken along line I-I′ of the semiconductor device of FIG. 2A according to some implementations. FIG. 2C is a cross-sectional view taken along line II-II′ of the semiconductor device of FIG. 2A according to some implementations.

The semiconductor device 10 may include a peripheral circuit region PERI, a first semiconductor structure including a substrate 201, and a memory cell region CELL, a second semiconductor structure including a plate layer 101. The memory cell region CELL may be disposed on the peripheral circuit region PERI. The memory cell array 20 of FIG. 1A may be disposed in the memory cell region CELL, and the peripheral circuit 30 of FIG. 1A may be disposed in the peripheral circuit region PERI. In some implementations, the memory cell region CELL may be disposed below the peripheral circuit region PERI.

The peripheral circuit region PERI may include a substrate 201, first and second impurity regions 205 and 206 in the substrate 201, element isolating layers 209, first and second circuit elements 230a and 230b disposed on the substrate 201, a peripheral region insulating structure 280, and a capacitor structure 200.

The substrate 201 may include first, second and third regions R1, R2 and R3. The first, second and third regions R1, R2 and R3 may be disposed side by side in a first direction (X-direction). In another example, the second region R2 may be surrounded by the first and third regions R1 and R3. In this case, the first and third regions R1 and R3 may be a single region, and may be a region in which a peripheral circuit (e.g., a peripheral circuit 30 of FIG. 1A) is disposed. The second region R2 may be a region in which a capacitor structure 200 is disposed.

The first circuit elements 230a and peripheral interconnection structures 250, 260 and 270 connected to the first circuit elements 230a may be disposed on the first and third regions R1 and R3. The second region R2 may be disposed between the first region R1 and the third region R3, and the second circuit element 230b and second lower contact plugs 240 connected to the second circuit element 230b, and the capacitor structure 200 may be arranged on the second region R2.

The substrate 201 may have an upper surface extending in the first direction (X-direction) and a second direction (Y-direction). An active region may be defined by the element isolating layer 209 in the substrate 201. The first impurity regions 205 including impurities may be disposed in a portion of the active region defined by the element isolating layer 209 disposed in the first and third regions R1 and R3. The second impurity regions 206 including impurities may be disposed in a portion of the active region defined by the element isolating layer 209 disposed in the second region R2. The substrate 201 may include a semiconductor material, such as a group IV semiconductor, a group III-V compound semiconductor, or a group II-VI compound semiconductor. The substrate 201 may be provided as a bulk wafer or an epitaxial layer. For example, the substrate 201 may be bulk silicon or silicon-on-insulator (SOI).

The first and second circuit elements 230a and 230b may include planar transistors. The first circuit elements 230a may be disposed on the first and third regions R1 and R3, and the second circuit element 230b may be disposed on the second region R2. In an example, each of the first circuit elements 230a may include a first peripheral gate dielectric layer 232a, a first peripheral gate electrode 235a on the first peripheral gate dielectric layer 232a, and a first peripheral gate spacer 234a on a side surface of the first peripheral gate dielectric layer 232a and a side surface of the first peripheral gate electrode 235a. Each of the second circuit elements 230b may include a second peripheral gate dielectric layer 232b, a second peripheral gate electrode 235b on the second peripheral gate dielectric layer 232b, and a second peripheral gate spacer 234b on a side surface of the second peripheral gate dielectric layer 232b and a side surface of the second peripheral gate electrode 235b.

The first impurity regions 205 may be disposed as source/drain regions in the substrate 201 on both sides of the first peripheral gate electrode 235a of the first circuit element 230a. The first impurity regions 205 may include a first source/drain region 205a and a second source/drain region 205b disposed on both sides of the first peripheral gate electrode 235a.

The second impurity region 206 may be disposed as a source/drain region in the substrate 201 on both sides of the second peripheral gate electrode 235b of the second circuit element 230b. The second impurity regions 206 may include a third source/drain region 206a and a fourth source/drain region 206b disposed on both sides of the second peripheral gate electrode 235b.

The peripheral region insulating structure 280 may be disposed on the first and second circuit elements 230a and 230b. The peripheral region insulating structure 280 may include a plurality of insulating layers formed at different process operations. The peripheral region insulating structure 280 may include an insulating material. The peripheral region insulating structure 280 may include silicon oxide, silicon nitride, silicon oxynitride, silicon carbonitride, a low-κ dielectric, or combinations thereof. For example, the peripheral region insulating structure 280 may include silicon oxide.

The peripheral interconnection structures 250, 260 and 270 may be disposed on the first and third regions R1 and R3. The peripheral interconnection structures 250, 260 and 270 may include first lower contact plugs 250, peripheral interconnection lines 260, and first peripheral contact plugs 270 disposed on different levels from the peripheral interconnection lines 260. The first lower contact plugs 250 and the first peripheral contact plugs 270 may have a pillar shape, and the peripheral interconnection lines 260 may have a line shape. The peripheral interconnection structures 250, 260 and 270 may include a conductive material. For example, the peripheral interconnection structures 250, 260 and 270 may include tungsten (W), copper (Cu), and aluminum (Al), and each of the components may further include a diffusion barrier.

An electrical signal may be applied to the first circuit elements 230a by the peripheral interconnection structures 250, 260 and 270. The first lower contact plugs 250 may be electrically connected to the first circuit elements 230a and the first impurity regions 205. The peripheral interconnection lines 260 may be disposed on the first lower contact plugs 250 and may be connected to the first lower contact plugs 250, and may extend in the second direction (Y-direction). The first peripheral contact plugs 270 may be disposed on different levels from the peripheral interconnection lines 260, and may connect the peripheral interconnection lines 260 to each other. In an example, the peripheral interconnection lines 260 and the first peripheral contact plugs 270 may be disposed on the same level as the capacitor structure 200 described below.

In the present disclosure, the peripheral interconnection structure 250, 260 and 270 disposed on the first region R1 and the peripheral region insulating structure 280 surrounding the peripheral interconnection structure 250, 260 and 270 disposed on the first region R1 may be referred to as a first interconnection structure, and the peripheral interconnection structure 250, 260 and 270 disposed on the third region R3 and the peripheral region insulating structure 280 surrounding the peripheral interconnection structure 250, 260 and 270 disposed on the third region R3 may be referred to as a second interconnection structure.

The second lower contact plugs 240 may be disposed between the second circuit element 230b and the capacitor structure 200 on the second region R2. The second lower contact plugs 240 may be electrically connected to the second circuit element 230b and the second impurity regions 206. A peripheral region insulating structure 280 may be disposed to cover side surfaces of the second lower contact plugs 240 and the second circuit element 230b. In an example, the second lower contact plugs 240 of the second region R2 may be disposed on the same level as the first lower contact plugs 250 of the first and third regions R1 and R3.

The capacitor structure 200 may be disposed on the second region R2 of the substrate 201. The capacitor structure 200 may be disposed on the second lower contact plugs 240 so as to overlap the second lower contact plugs 240 in a vertical direction (Z-direction). The capacitor structure 200 may perform a function of storing a charge. The capacitor structure 200 may form a pumping capacitor CAP1 of the charge pump circuit 56 and 56a described above with reference to FIGS. 1A and 1B. The capacitor structure 200 may include a first electrode structure 210, a second electrode structure 220 spaced apart from the first electrode structure 210 in the first direction (X-direction), and a dielectric capacitor structure 290 filling a space between the first electrode structure 210 and the second electrode structure 220.

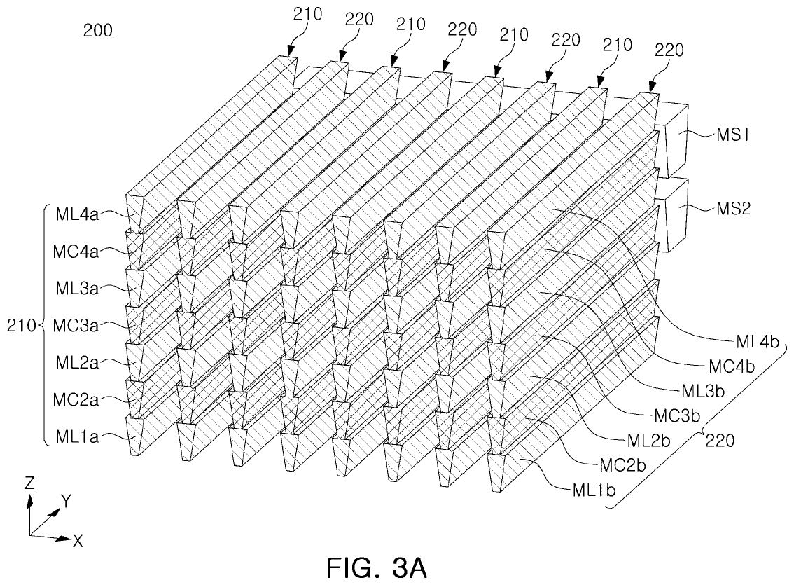

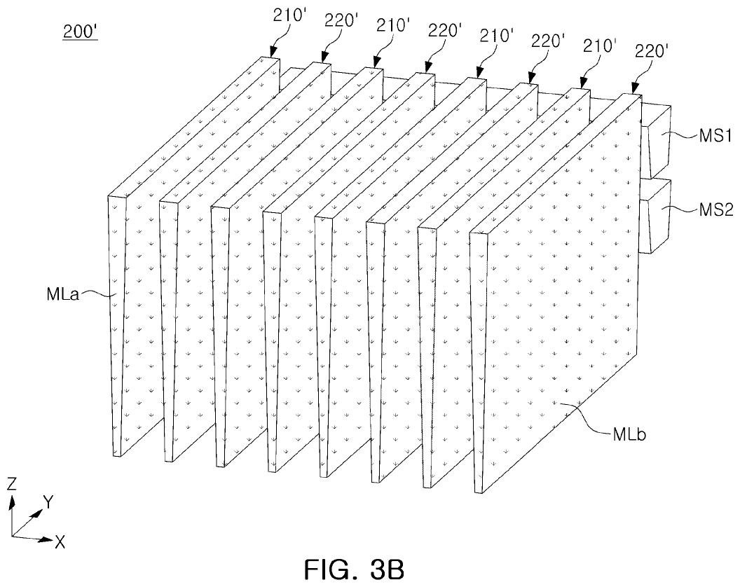

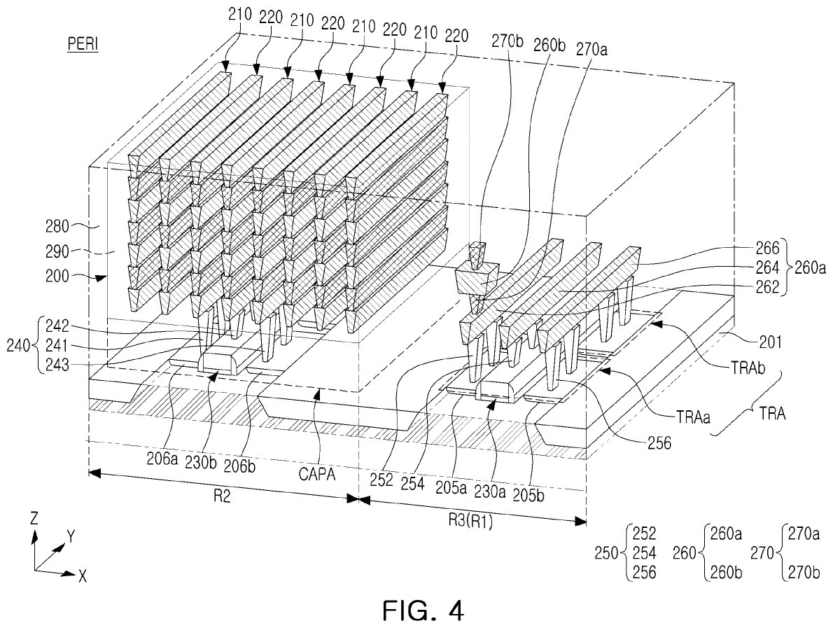

The first electrode structures 210 and the second electrode structures 220 spaced apart from each other in the first direction (X-direction) may include a conductive material. For example, the first electrode structures 210 and the second electrode structures 220 may include tungsten (W), copper (Cu), and aluminum (Al), and each of the components may further include a diffusion barrier. The dielectric capacitor structure 290 may include a high-κ material. The high-κ material may denote a dielectric material having a dielectric constant higher than silicon oxide (SiO₂). The high-κ material may mean a dielectric material having a dielectric constant higher than silicon oxide (SiO₂). The high dielectric constant material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). In an example, the dielectric capacitor structure 290 may have a first dielectric constant, and the first dielectric constant may be greater than a second dielectric constant of the peripheral region insulating structure 280. The capacitor structure 200 will be described in detail below with reference to FIGS. 3A, 3B and 4.

A semiconductor device may include a capacitor structure 200 and peripheral interconnection lines 260 and first peripheral contact plugs 270 disposed on the same level as the capacitor structure 200, and the dielectric capacitor structure 290 of the capacitor structure 200 may include a material having a higher dielectric constant than that of a peripheral region insulating structure 280 surrounding the peripheral interconnection structures 250, 260 and 270. Accordingly, the capacitance of the capacitor structure 200 may be increased, thereby providing a semiconductor device having improved electrical characteristics.

The memory cell region CELL may include a first memory region CA1 and a second memory region CA2. The memory cell region CELL may include a source structure SS including the plate layer 101, gate electrodes 130 stacked on the source structure SS and included in a gate structure GS, interlayer insulating layers 120 alternately stacked with the gate electrodes 130 and included in the gate structure GS, channel structures CH disposed to penetrate the gate structure GS in the first memory region CA1, first separation regions MS extending by penetrating through the gate structure GS, second separation regions US extending by penetrating through some of the gate electrodes 130 disposed on an upper portion, and contact plugs 170 connected to the gate electrodes 130 and extending vertically in the second memory region CA2. In an example, the memory cell region CELL may further include a horizontal insulating layer 110 disposed below the gate electrodes 130 in the second memory region CA2, substrate insulating layers 121 disposed to penetrate through the plate layer 101, studs 180 on the channel structure CH and the contact plugs 170, and first to third cell region insulating layers 192, 194 and 196 covering the gate electrodes 130.

In the memory cell region CELL, the first memory region CA1 may be a region in which the gate electrodes 130 are vertically stacked and the channel structure CH is disposed, and may be a region in which memory cells are disposed. The second memory region CA2 may be a region in which the gate electrodes 130 are extended by different lengths to form gate pad regions GP, and may correspond to a region for electrically connecting the memory cells to the peripheral circuit region PERI. The second memory region CA2 may be disposed at least in one end of the first memory region CA1 at least in one direction, for example, in the first direction (X-direction). In this document, the first memory region CA1 may be referred to as a memory cell array region, and the second memory region CA2 may be referred to as a stepwise region.

The source structure SS may include a plate layer 101, a first horizontal conductive layer 102, and a second horizontal conductive layer 104 sequentially stacked in the first memory region CA1. However, in some implementations, the number of conductive layers of the source structure SS may be variously changed. In the present disclosure, the source structure SS may be referred to as a stacked pattern.

The plate layer 101 has a plate shape and may function as at least a portion of a common source line of a semiconductor device 10. The plate layer 101 may have an upper surface extending in the first direction (X-direction) and the second direction (Y-direction). The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer such as a polycrystalline silicon layer, or an epitaxial layer.

The first and second horizontal conductive layers 102 and 104 may be sequentially stacked and arranged on an upper surface of the plate layer 101 in the first memory region CA1. The first horizontal conductive layer 102 may not extend to the second memory region CA2, and the second horizontal conductive layer 104 may extend to the second memory region CA2. The first horizontal conductive layer 102 may function as a portion of a common source line of the semiconductor device 10, and may function, for example, as a common source line together with the plate layer 101. As illustrated in FIG. 2C, the first horizontal conductive layer 102 may be directly connected to a channel layer 140 around the channel layer 140. The second horizontal conductive layer 104 may be in contact with the plate layer 101 in some regions of the second memory region CA2 in which the first horizontal conductive layer 102 and the horizontal insulating layer 110 are not disposed.

The first and second horizontal conductive layers 102 and 104 may include a semiconductor material, and may include, for example, polycrystalline silicon. In this case, at least the first horizontal conductive layer 102 may be a layer doped with impurities of the same conductive type as the plate layer 101, and the second horizontal conductive layer 104 may be a doped layer or a layer including impurities diffused from the first horizontal conductive layer 102. However, the material of the second horizontal conductive layer 104 is not limited to a semiconductor material, and may also be replaced with an insulating layer.

The horizontal insulating layer 110 may be disposed on the plate layer 101 on the same level as the first horizontal conductive layer 102 in at least a portion of the second memory region CA2. The horizontal insulating layer 110 may include first and second horizontal insulating layers 111 and 112 alternately stacked on the second memory region CA2 of the plate layer 101. The horizontal insulating layer 110 may be a layer remaining after a portion of the semiconductor device 10 is replaced with the first horizontal conductive layer 102 during a manufacturing process of the semiconductor device 10.

The horizontal insulating layer 110 may include silicon oxide, silicon nitride, silicon carbide, or silicon oxynitride. The first horizontal insulating layer 111 and the second horizontal insulating layer 112 may include different insulating materials. For example, the first horizontal insulating layers 111 may be formed of the same material as the interlayer insulating layers 120, and the second horizontal insulating layer 112 may be formed of a different material from the interlayer insulating layers 120.

The substrate insulating layers 121 may be disposed to penetrate through the plate layer 101, the horizontal insulating layer 110, and the second horizontal conductive layer 104 in a portion of the second memory region CA2. The substrate insulating layers 121 may be further disposed in the first memory region CA1, for example, in a region in which a through-via extending from the memory cell region CELL to the peripheral circuit region PERI is disposed. An upper surface of the substrate insulating layer 121 may be coplanar with an upper surface of the second horizontal conductive layer 104. The substrate insulating layer 121 may include an insulating material, for example, silicon oxide, silicon nitride, silicon carbide, or silicon oxynitride.

The gate electrodes 130 may be vertically spaced apart from each other and stacked on the plate layer 101 to form a gate structure GS together with the interlayer insulating layers 120. The gate structure GS may include first, second and third stack structures GS1, GS2 and GS3, which are vertically stacked. However, according to some implementations, the number of stack structures of the gate structure GS may be varied. For example, the gate structure GS may be formed of four or more stack structures, or may be formed of a single stack structure or two stack structures. The number of gate electrodes 130 included in each of the first, second and third stack structures GS1, GS2 and GS3 may be the same or different.

The gate electrodes 130 may include lower gate electrodes 130L included in a gate of a ground select transistor, memory gate electrodes 130M of a plurality of memory cells, and upper gate electrodes 130U included in gates of string select transistors. The number of memory gate electrodes 130M included in the memory cells may be determined according to the capacity of the semiconductor device 10. According to some implementations, the number of upper and lower gate electrodes 130U and 130L may be 1 to 4 or more, respectively, and the upper and lower gate electrodes 130U and 130L may have a structure identical to or different from that of the memory gate electrodes 130M. In some implementations, the gate electrodes 130 may further include gate electrodes 130 disposed adjacently to the upper gate electrodes 130U and/or the lower gate electrodes 130L and forming an erase transistor used for an erase operation utilizing a gate induced drain leakage (GIDL) phenomenon. Additionally, some of the gate electrodes 130, for example, memory gate electrodes 130M adjacent to the upper or lower gate electrodes 130U and 130L, may be dummy gate electrodes.

In FIG. 2A, the gate electrodes 130 may be separated from each other in the second direction (Y-direction) by first separation regions MS extending continuously in the first memory region CA1 and the second memory region CA2. The gate electrodes 130 between a pair of first separation regions MS may form one memory block, but the range of the memory block is not limited thereto. Some of the gate electrodes 130, for example, each of the memory gate electrodes 130M, may form one layer within one memory block.

The gate electrodes 130 may be vertically spaced apart from each other and stacked on the first memory region CA1, and may extend from the first memory region CA1 to the second memory region CA2 by different lengths to form stepwise-shaped step structures in the gate pad regions GP. The gate pad regions GP may be defined as regions including gate pads connected to the contact plugs 170 of the gate electrodes 130. In FIG. 2B, the gate electrodes 130 may have a form in which gate electrodes 130 are removed from an upper portion of one of the first to third stack structures GS1, GS2 and GS3 by a predetermined depth in the gate pad regions GP. The gate pad regions GP may be disposed so as not to overlap each other in the third direction (Z-direction), which is a vertical direction. On the gate pad regions GP of the first and second stack structures GS1 and GS2 in a lower portion, the gate electrodes 130 included in the second and third stack structures GS2 and GS3 may extend horizontally. In some implementations, the gate pad regions GP may be disposed in order from the first region R1 in the first direction (X-direction) to the third stack structure GS3, the second stack structure GS2, and the first stack structure GS1. Only one gate pad region GP is illustrated in each of the first, second and third gate stack structures GS1, GS2 and GS3, but a plurality of gate pad region GPs may be disposed in each of the first, second and third gate stack structures GS1, GS2 and GS3. However, in some implementations, an arrangement shape, an arrangement order, and a depth of the gate pad regions GP may be variously changed. In an example, the gate electrodes 130 may not be disposed on the gate pad regions GP.

The gate electrodes 130 may form first and second step structures in an asymmetrical shape in the first direction (X-direction) in each gate pad region GP. The first step structure may be a stepwise structure that is relatively adjacent to the first memory region CA1 and has a lower level in the first direction (X-direction), and the second step structure may be a stepwise structure that is relatively distant from the first memory region CA1 and has a higher level in the first direction (X-direction). For example, an inclination of the first step structure in each of the gate pad areas GP may be less than an inclination of the second step structure in the first memory region CA1. However, in some implementations, the first and second step structures may have a symmetrical shape. In the first step structure, the gate electrodes 130 may be connected to the contact plugs 170, and in the second step structure, the gate electrodes 130 may form a dummy region or dummy structure not connected to the contact plugs 170. In example embodiments, the specific shape of the step structure, the number of gate electrodes 130 included in each step structure, and the like, are not limited to the form illustrated in FIG. 2B. In some implementations, the gate electrodes 130 may be disposed to have a step structure in the second direction (Y-direction). The gate electrodes 130 may include contact regions 130P connected to contact plugs 170. The contact regions 130P are regions of the gate electrode layer not covered with other gate electrodes in one stack structure, and may be defined as regions in which gate pads in contact with surrounding contact plugs 170 in each of the stack structures GS disposed in the second memory region CA2 are disposed.

The gate electrodes 130 may include a metallic material, for example, tungsten (W). According to some implementations, the gate electrodes 130 may include polycrystalline silicon or a metal silicide material. In some implementations, the gate electrodes 130 may further include a diffusion barrier, and the diffusion barrier may include, for example, tungsten nitride (WN), tantalum nitride (TaN), titanium nitride (TiN), or combinations thereof.

The interlayer insulating layers 120 may be disposed between the gate electrodes 130. The interlayer insulating layers 120 may also be disposed so as to be spaced apart from each other in a direction, perpendicular to the upper surface of the plate layer 101, and extend in the first direction (X-direction), similar to the gate electrodes 130. In each of the first, second and third stack structures GS1, GS2 and GS3, thicknesses of the interlayer insulating layers 120 may not all be the same. In an example, at least some of the interlayer insulating layers 120 may have different thicknesses. Additionally, the number of interlayer insulating layers 120 may be variously changed from that illustrated. The interlayer insulating layers 120 may include an insulating material such as silicon oxide or silicon nitride.

Each of the channel structures CH may form a single memory cell string, and the channel structures CH may be spaced apart from each other in rows and columns on the plate layer 101 in the first memory region CA1. The channel structures CH may be disposed to form a grid pattern in an X-Y plane, or may be disposed in a zigzag shape in one direction. The channel structures CH may have a pillar shape and may have inclined side surfaces that become narrower as the channel structures CH approach the plate layer 101 depending on the aspect ratio. According to an example embodiment, at least some of the channel structures CH disposed in an end of the first memory region CA1 may be dummy channel structures.

In FIG. 2C, each of the channel structures CH may include first, second, and third channel portions CH1, CH2, and CH3 stacked in a vertical direction (Z-direction). The first, second, and third channel portions CH1, CH2, and CH3 may penetrate through the first, second, and third stack structures GS1, GS2, and GS3 of the gate structure GS, respectively. The channel structure CH may have a form in which the first channel portion CH1, a second channel portion CH2 in an upper portion of the first channel portion CH1, and a third channel portion CH3 in an upper portion of the second channel portion CH2 are connected. The first, second, and third channel portions CH1, CH2, and CH3 may have a form in which a width of an upper surface of the channel portion disposed in a lower portion is greater than a width of a lower surface of the channel portion disposed in an upper portion, in a region or an interface in which the first, second, and third channel portions CH1, CH2, and CH3 are connected to each other. The channel structure CH may have bent portions due to a difference in width in the interface between the first, second, and third channel portions CH1, CH2, and CH3. However, according to some implementations, the number of channel portions stacked in the third direction (Z-direction) in the channel structure CH may be variously changed. The first channel portion CH1 may further penetrate through the source structure SS, and a lower portion of the first channel portion CH1 may be disposed in the plate layer 101.

Each of the channel structures CH may include a channel layer 140, a gate dielectric layer 145, a channel-buried insulating layer 147, and a channel pad 149, disposed in a channel hole. The channel layer 140, the gate dielectric layer 145, and the channel-buried insulating layer 147 may be connected to each other between the first, second, and third channel portions CH1, CH2, and CH3.

The channel layer 140 may be formed in an annular shape surrounding the internal channel-buried insulating layer 147, but may also have a columnar shape such as a cylinder or a prism without the channel-buried insulating layer 147 according to some implementations. The channel layer 140 may be connected to the first horizontal conductive layer 102 in a lower portion. The channel layer 140 may include a semiconductor material, such as polycrystalline silicon or single-crystal silicon.

The gate dielectric layer 145 may be disposed between the gate electrodes 130 and the channel layer 140. The gate dielectric layer 145 may include a tunneling layer, a charge storage layer, and a blocking layer, which are sequentially stacked from the channel layer 140. The tunneling layer may tunnel charges into the charge storage layer, and may include, for example, silicon oxide (SiO₂), silicon nitride (Si₃N₄), silicon oxynitride (SiON), or combinations thereof. The charge storage layer may be a charge trapping layer or a floating gate conductive layer. The blocking layer may include silicon oxide (SiO₂), silicon nitride (Si₃N₄), silicon oxynitride (SiON), a high-κ dielectric material, or combinations thereof. In some implementations, at least a portion of the gate dielectric layer 145 may extend in a horizontal direction along the gate electrodes 130.

The channel pad 149 may be disposed only in an upper end of the third channel portion CH3 in an upper portion. The channel pad 149 may include, for example, doped polycrystalline silicon.

The first separation regions MS may be disposed to extend in the first direction (X-direction) by penetrating through at least some of the gate electrodes 130. In FIG. 2A, the first separation regions MS may be disposed to be parallel to each other. Some of the separation regions MS may extend into one along the first memory region CA1 and the second memory region CA2, and others thereof may extend only to a portion of the second memory region CA2, or the separation regions MS may be disposed intermittently in the first memory region CA1 and the second memory region CA2. However, in some implementations, the arrangement form and the number of the first separation regions MS, and the like, are not limited to those shown in FIG. 2A.

The first separation regions MS may penetrate through the gate electrodes 130 stacked on the plate layer 101, and may further penetrate through the first and second horizontal conductive layers 102 and 104 therebelow to be connected to the plate layer 101. The first separation regions MS may have a shape in which a width thereof decreases toward the plate layer 101 due to a high aspect ratio. For example, a side surface of the first separation regions MS may have a substantially constant inclination so that the width thereof continuously or continuously decreases, and may not have a bent portion on the side surface.

A gate separation insulating layer 105 may be disposed in each of the first separation regions MS. The gate separation insulating layer 105 may include an insulating material, and may include, for example, silicon oxide, silicon nitride, or silicon oxynitride.

In FIGS. 2A to 2C, the second separation regions US may extend in the first direction (X-direction) between the first separation regions MS adjacent to each other. The second separation regions US may be disposed in a portion of the second region R2 and the first memory region CA1. The second separation regions US may penetrate through some of the gate electrodes 130 including an upper gate electrode 130U in an uppermost portion, among the gate electrodes 130. The second separation regions US may, for example, separate a total of three gate electrodes 130 from each other in the second direction (Y-direction). However, in some implementations, the number of gate electrodes 130 separated by the second separation regions US may be variously changed.

Each of the second separation regions US may include an upper separation insulating layer 103. The upper separation insulating layer 103 may include an insulating material, and may include, for example, silicon oxide, silicon nitride, or silicon oxynitride.

The contact plugs 170 may be connected to the contact regions 130P of the gate electrodes 130 in the gate pad regions GP in the second memory region CA2. The contact plugs 170 may penetrate through at least a portion of the cell region insulating layers 192 194 and 196, and may be connected to each of the contact regions 130P of the gate electrodes 130 exposed upwardly. The contact plugs 170 may penetrate through the gate electrodes 130 above and below the contact regions 130P, and may penetrate through the second horizontal conductive layer 104, the horizontal insulating layer 110 and the plate layer 101 to be connected to the peripheral interconnection structures 250, 260 and 270 in the peripheral circuit region PERI. The contact plugs 170 may be spaced apart from the gate electrodes 130 above and below the contact regions 130P by contact insulating layers 160. The contact plugs 170 may be spaced apart from the plate layer 101, the horizontal insulating layer 110, and the second horizontal conductive layer 104 by the substrate insulating layers 121.

The contact plugs 170 may have a shape corresponding to the channel structures CH. Each of the contact plugs 170 may include first to third contact portions MC1, MC2, and MC3 stacked from a lower portion. The first, second, and third contact portions MC1, MC2, and MC3 may penetrate through the first, second, and third stack structures GS1, GS2, and GS3 of the gate structure GS, respectively. The first contact portion MC1 may further penetrate through the substrate insulating layer 121. The first to third contact portions MC1, MC2, and MC3 may have a cylindrical shape in which a width thereof decreases toward the substrate 201 due to an aspect ratio. Each of the first to third contact portions MC1, MC2, and MC3 may have a substantially constant inclination. The first contact portion MC1 may further include a landing region in which a width thereof is expanded below the substrate insulating layer 121. However, in some implementations, the first contact portion MC1 may not include the landing region.

The first, second, and third contact portions MC1, MC2, and MC3 may have a form in which a width of an upper surface of the contact portion disposed in a lower portion is greater than a width of a lower surface of the contact portion disposed in an upper portion, in a region or an interface in which the first, second, and third contact portions MC1, MC2, and MC3 are connected to each other. Accordingly, similar to the channel structure CH, the contact plug 170 may also have bent portions due to a difference in width at the interface between the first, second, and third contact portions MC1, MC2, and MC3.

A level of an interface between the first contact portion MC1 and the second contact portion MC2 may be the same as a level of an interface between the first channel portion CH1 and the second channel portion CH2. In an example, a level of an upper surface of the first contact portion MC1 may be the same as a level of an upper surface of the first channel portion CH1, and a level of an upper surface of the second contact portion MC2 may be the same as a level of an upper surface of the second channel portion CH2.

The contact plugs 170 may include a conductive material, and may include, for example, at least one of tungsten (W), copper (Cu), aluminum (Al), or alloys thereof. In some implementations, the contact plugs 170 may include a barrier layer extending along a side surface and a bottom surface thereof, or may have an air gap therein.

The contact insulating layers 160 may be disposed to surround side surfaces of each of the contact plugs 170 above and below the contact regions 130P. The contact insulating layers 160 may be spaced apart from each other in the third direction (Z-direction) around each of the contact plugs 170. The contact insulating layers 160 may extend horizontally from the side surfaces of each of the contact plugs 170 by substantially the same length. The contact insulating layers 160 may be disposed on substantially the same level as the gate electrodes 130, respectively. The contact insulating layers 160 may include an insulating material, and may include, for example, silicon oxide, silicon nitride, or silicon oxynitride.

The studs 180 may be included in a cell interconnection structure electrically connected to memory cells in a memory cell region CELL. The studs 180 may be connected to the channel structures CH and the contact plugs 170, and may be electrically connected to the channel structures CH and gate electrodes 130. The studs 180 are illustrated in a plug shape, but the present disclosure is not limited thereto, and the studs 180 and may also have a line shape. In some implementations, the number of plugs and interconnection lines included in the cell interconnection structure may be variously changed. The studs 180 may include a metal, and may include, for example, tungsten (W), copper (Cu), and aluminum (Al).

The first to third cell region insulating layers 192, 194, and 196 may be disposed to cover the first, second, and third stack structures GS1, GS2, and GS3, respectively. The first to third cell region insulating layers 192, 194, and 196 may be disposed in an uppermost portion of the first, second, and third stack structures GS1, GS2, and GS3. The first, second, and third cell region insulating layers 192, 194, and 196 may be formed of an insulating material, and may be formed of a plurality of insulating layers. When the first, second, and third cell region insulating layers 192, 194, and 196 include the same material as the interlayer insulating layers 120, interfaces with the interlayer insulating layers 120 may not be distinguished. The first, second, and third cell region insulating layers 192, 194, and 196 and the interlayer insulating layers 120 may be collectively referred to as interlayer insulating layers in the present disclosure.

In the present disclosure, the first direction (X-direction) and the second direction (Y-direction) may be perpendicular to each other in a direction, parallel to an upper surface of the substrate 201. The first direction (X-direction) and the second direction (Y-direction) may be perpendicular to the third direction (Z-direction). The horizontal direction may refer to the first direction (X-direction) and the second direction (Y-direction), and a vertical direction may refer to the third direction (Z-direction).

FIG. 3A is a perspective view illustrating examples of first electrode structures and second electrode structures of a capacitor structure of the semiconductor device of FIG. 2A according to some implementations. In FIG. 3A, a capacitor structure 200 may include first electrode structures 210 and second electrode structures 220. Each of the first electrode structures 210 includes first portions ML1a, MC2a, ML2a, MC3a, ML3a, MC4a, and ML4a and each of the second electrode structures 220 includes second portions ML1b, MC2b, ML2b, MC3b, ML3b, MC4b, and ML4b. Each of the first electrode structure 210 and each of the second electrode structure 220 may be arranged alternately in the first direction (X-direction). In an example, the capacitor structure 200 may further include a dielectric capacitor structure (e.g., a dielectric capacitor structure 290 of FIG. 2B) filling a space between the first electrode structures 210 and the second electrode structures 220.

The first electrode structure 210 and the second electrode structure 220 may have different potentials. In an example, each of the first electrode structure 210 and the second electrode structure 220 may receive an electrical signal through separate interconnection lines connected to each of the first electrode structure 210 and the second electrode structure 220. In an example, each of the first electrode structure 210 and the second electrode structure 220 may receive different electrical signals through the second lower contact plugs 240 of FIG. 2B. In this regard, reference will be made to FIG. 4 as described below.

Each of the first electrode structures 210 and the second electrode structures 220 may have a plate shape, and may be formed by stacking a plurality of electrodes. The first electrode structures 210 may include a plurality of first portions ML1a, MC2a, ML2a, MC3a, ML3a, MC4a, and ML4a spaced apart from each other in the first direction (X-direction) and extending in the second direction (Y-direction) and a vertical direction (Z-direction), and the second electrode structures 220 may include a plurality of second portions ML1b, MC2b, ML2b, MC3b, ML3b, MC4b, and ML4b arranged alternately with the first electrode structures 210 in the first direction (X-direction) and extending in the second direction (Y-direction) and the vertical direction (Z-direction).

The first and second electrode structures 210 and 220 may be formed by a single damascene process.

The first portions ML1a, MC2a, ML2a, MC3a, ML3a, MC4a, and ML4a of the first electrode structure 210 may include a first-first lower electrode ML1a, a second-first lower electrode MC2a, a second-second lower electrode ML2a, a first-first intermediate electrode MC3a, a first-second intermediate electrode ML3a, a first-first upper electrode MC4a, and a first-second upper electrode ML4a, which are sequentially stacked in the third direction (Z-direction).

Each of the first-first lower electrode ML1a, the second-first lower electrode MC2a, the second-second lower electrode ML2a, the first-first intermediate electrode MC3a, the first-second intermediate electrode ML3a, the first-first upper electrode MC4a and the first-second upper electrode ML4a may have an inclined side surface in which a width thereof becomes narrower toward a lower portion, and may have a plate shape (or wall type) extending in the second direction (Y-direction) and the vertical direction (Z-direction).

The second portions ML1b, MC2b, ML2b, MC3b, ML3b, MC4b, and ML4b of the second electrode structure 220 may include a first-second lower electrode ML1b, a third-first lower electrode MC2b, a third-second lower electrode ML2b, a second-first intermediate electrode MC3b, a second-second intermediate electrode ML3b, a second-first upper electrode MC4b, and a second-second upper electrode ML4b, which are sequentially stacked in the third direction (Z-direction). The second electrode structure 220 may have the same structure as the first electrode structure 210.

Each of the first-second lower electrode ML1b, the third-first lower electrode MC2b, the third-second lower electrode ML2b, the second-first intermediate electrode MC3b, the second-second intermediate electrode ML3b, the second-first upper electrode MC4b, and the second-second upper electrode ML4b may have an inclined side surface in which a width thereof becomes narrower toward a lower portion, and may have a plate shape (or wall type) extending in the second direction (Y-direction) and the vertical direction (Z-direction).

In an example, the first-first and first-second lower electrodes ML1a and ML1b, the second-second and third-second lower electrodes ML2a and ML2b, the first-second and second-second intermediate electrodes ML3a and ML3b, and the first-second and second-second upper electrodes ML4a and ML4b may be disposed on the same level as the peripheral interconnection lines 260 of FIG. 2B and may be formed in the same process.

The second-first and third-first lower electrodes MC2a and MC2b, the first-first and second-first intermediate electrodes MC3a and MC3b, and the first-first and second-first upper electrodes MC4a and MC4b may be disposed on the same level as the first peripheral contact plugs 270 of FIG. 2B and may be formed in the same process.

The first electrode structure 210 and the second electrode structure 220 may include a conductive material. For example, the first electrode structure 210 may include a metal such as tungsten (W), titanium (Ti), tantalum Ta, copper (Cu), and aluminum (Al), but the present disclosure is not limited thereto.

Each of the first portions ML1a, MC2a, ML2a, MC3a, ML3a, MC4a, and ML4a of the first electrode structure 210 and the second portions ML1b, MC2b, ML2b, MC3b, ML3b, MC4b, and ML4b of the second electrode structure 220 is illustrated as including seven electrodes, but the present disclosure is not limited thereto, and the number of electrodes included in the first electrode structure 210 and the second electrode structure 220 may be variously changed.

The capacitor structure 200 may further include a first strap portion MS1 connecting the first electrode structures 210 and a second strap portion MS2 connecting the second electrode structures 220. In an example, the first strap portion MS1 may be disposed on one side of the first electrode structures 210 facing the second direction (Y-direction), and may be in the form of a bar extending in the first direction (X-direction), and the first electrode structures 210 may extend from the first strap portion MS1. The first electrode structures 210 may be connected to each other through the first strap portion MS1. The second strap portion MS2 may be disposed on one side of the second electrode structure 220 facing the second direction (Y-direction), and may be in the form of a bar extending in the first direction (X-direction), and the second electrode structure 220 may extend from the second strap portion MS2. The second electrode structures 220 may be connected to each other through the second strap portion MS2. The second strap portion MS2 may overlap the first strap portion MS1 in the third direction (Z-direction). However, the present disclosure is not limited thereto, and the first strap portion MS1 and the second strap portion MS2 may be spaced apart from each other in the second direction (Y-direction) with the first and second electrode structures 210 and 220 interposed therebetween.

FIG. 3B is a perspective view illustrating examples of first electrode structures and second electrode structures of a capacitor structure of the semiconductor device of FIG. 2A according to some implementations. In FIG. 3B, a capacitor structure 200′ may include first electrode structures 210′ and second electrode structures 220′.

First portions MLa included in the first electrode structures 210′ and second portions MLb included in the second electrode structures 220′ may be arranged alternately in the first direction (X-direction). In an example, the capacitor structure 200′ may further include a capacitor dielectric layer (e.g., the dielectric capacitor structure 290 of FIG. 2B) filling a space between the first electrode structures 210′ and the second electrode structures 220′.

Each of the first electrode structures 210′ and the second electrode structures 220′ may have a plate shape. Each of the first portions MLa of the first electrode structures 210′ and the second portions MLb of the second electrode structures 220′ may have a high aspect ratio contact (HARC) structure, and may have a width that narrows toward a lower portion.

The capacitor structure 200′ may further include a first strap portion MS1 connecting the first electrode structure 210′ and a second strap portion MS2 connecting the second electrode structure 220′. In an example, the first strap portion MS1 may be disposed on one side of the first electrode structure 210′ facing the second direction (Y-direction), and may be in the form of a bar extending in the first direction (X-direction), and the first portions MLa of the first electrode structure 210′ may extend from the first strap portion MS1. The second strap portion MS2 may be disposed on one side of the second electrode structure 220′ facing the second direction (Y-direction), and may be in the form of a bar extending in the first direction (X-direction), and the second portions MLb of the second electrode structure 220′ may extend from the second strap portion MS2.

FIG. 4 is a schematic perspective view illustrating an example of a peripheral circuit region of a semiconductor device according to some implementations. FIG. 4 is a perspective view of a peripheral circuit region PERI including a substrate 201 including a second region R2 and a third region R3 (or a first region R1) of the substrate 201.

In FIG. 4, the third region R3 (or the first region) of the peripheral circuit region PERI may include a circuit element arrangement region TRA, and the second region R2 of the peripheral circuit region PERI may include a capacitor arrangement region CAPA.

The first and second source/drain regions 205a and 205b, first circuit elements 230a, and peripheral interconnection structures 250, 260, and 270 may be disposed in the circuit element arrangement region TRA of the third region R3 (or the first region R1). The third and fourth source/drain regions 206a and 206b, second circuit elements 230b, and second lower contact plugs 240 may be disposed in the capacitor arrangement region CAPA. A peripheral region insulating structure 280 may cover the first circuit elements 230a and may be disposed on a side surface of the peripheral interconnection structure 250, 260, and 270.

The circuit element arrangement region TRA may be a region in which a Complementary Metal-Oxide-Semiconductor (CMOS) inverter is disposed, and may include a first arrangement region TRAa and a second arrangement region TRAb disposed to be parallel to the first arrangement region TRAa in the second direction (Y-direction). The first arrangement region TRAa may be a region in which a PMOS circuit element is disposed, and the second arrangement region TRAb may be a region in which an NMOS circuit element is disposed.

Each of the first arrangement region TRAa and the second arrangement region TRAb may include the first circuit elements 230a and the first and second source/drain regions 205a and 205b disposed on both sides of the first circuit elements 230a. The peripheral interconnection structure 250, 260, and 270 may include first lower contact plugs 250 to which the first and second source/drain regions 205a and 205b and the first circuit element 230a are connected, at least one peripheral interconnection line 260 on the first lower contact plugs 250, and at least one first peripheral contact plug 270 disposed on a different level from that of the at least one peripheral interconnection line 260.

The first lower contact plugs 250 may include first-first lower contact plugs 252 connected to the first source/drain region 205a, first-third lower contact plugs 256 connected to the second source/drain region 205b, and first-second lower contact plugs 254 connected to the first circuit element 230a. In an example, the first-first lower contact plugs 252, the first-second lower contact plugs 254, and the first-third lower contact plugs 256 may be spaced apart from each other in the first direction (X-direction). In an example, a height of each of the first-second lower contact plugs 254 in the vertical direction (Z-direction) may be less than a height of each of the first-first lower contact plugs 252 and the first-third lower contact plugs 256 in the vertical direction (Z-direction). In an example, upper surfaces of the first-first lower contact plugs 252, upper surfaces of the first-second lower contact plugs 254, and upper surfaces of the first-third lower contact plugs 256 may be coplanar with each other.

The peripheral interconnection lines 260 disposed on the first lower contact plugs 250 and extending in the second direction (Y-direction), and first peripheral contact plugs 270 disposed on different levels from the peripheral interconnection lines 260 may be disposed.

The peripheral interconnection lines 260 may include first peripheral interconnection lines 260a connected to the first lower contact plugs 250, and at least one second peripheral interconnection line 260b disposed on the first peripheral interconnection lines 260a and connected to the first peripheral interconnection lines 260a through a first-first peripheral contact plug 270a. The first peripheral interconnection lines 260a may include a first-first peripheral interconnection line 262 extending in the second direction (Y-direction) on the first-first lower contact plugs 252, a first-second peripheral interconnection line 264 extending in the second direction (Y-direction) on the first-second lower contact plugs 254, and a first-third peripheral interconnection line 266 extending in the second direction (Y-direction) on the first-third lower contact plugs 256.

The first peripheral contact plugs 270 may include the first-first peripheral contact plug 270a disposed on the first peripheral interconnection lines 260a and connecting the first peripheral interconnection line 260a and the second peripheral interconnection line 260b, and a first-second peripheral contact plug 270b disposed on the second peripheral interconnection lines 260b. The first-first peripheral contact plug 270a is illustrated as being disposed on the first-first peripheral interconnection line 262 of the first peripheral interconnection lines 260, but may be disposed on at least one of the first-second peripheral interconnection line 264 and the first-third peripheral interconnection line 266 of the first peripheral interconnection lines 260. The second peripheral interconnection line 260b may be disposed on the first-first peripheral contact plug 270a. The first-second peripheral contact plug 270b may be disposed on the second peripheral interconnection line 260b.

The second circuit element 230b, the third and fourth source/drain regions 206a and 206b disposed on both sides of the second circuit element 230b, the second lower contact plugs 240, and the capacitor structure 200 on the second circuit element 230b may be disposed in the capacitor arrangement region CAPA of the second region R2.

The second lower contact plugs 240 may include a second-first lower contact plug 241 connected to the third source/drain region 206a, a second-third lower contact plug 243 connected to the fourth source/drain region 206b, and a second-second lower contact plug 242 connected to the second circuit element 230b. The second-first lower contact plug 241, the second-second lower contact plug 242, and the second-third lower contact plug 243 may be spaced apart from each other in the first direction (X-direction), and a height of the second-second lower contact plug 242 in the vertical direction (Z-direction) may be less than heights of the second-first and second-third lower contact plugs 241 and 243. An upper surface of the second-first lower contact plug 241, an upper surface of the second-second lower contact plug 242, and an upper surface of the second-third lower contact plug 243 may be coplanar with each other.

The first lower contact plugs 250 may be disposed on the same level as the second lower contact plugs 240. Upper surfaces of the first lower contact plugs 250 may be coplanar with upper surfaces of the second lower contact plugs 240.

Side surfaces of the second lower contact plugs 240 may be surrounded by the peripheral region insulating structure 280.

The capacitor structure 200 may be disposed on the second lower contact plugs 240. The capacitor structure 200 may include the first electrode structures 210, the second electrode structures 220, and the dielectric capacitor structure 290 disposed between the first electrode structures 210 and the second electrode structures 220. Each of the first electrode structures 210 and the second electrode structures 220 may have a plate shape (or a wall shape). The dielectric capacitor structure 290 may have a hexahedral shape, and may accommodate the first electrode structures 210 and the second electrode structures 220.

The dielectric capacitor structure 290 included in the capacitor structure 200 in the peripheral circuit region PERI may be partially arranged in the capacitor arrangement region CAPA, and may secure the capacitance of the capacitor structure 200 by including a dielectric material having a higher permittivity than a permittivity of the peripheral region insulating structure 280. In an example, the dielectric capacitor structure 290 may be covered with the peripheral region insulating structure 280.

One of the first electrode structures 210 may be connected to the second-first lower contact plug 241, and another one of the first electrode structures 210 may be connected to the second-third lower contact plug 243. The first electrode structure 210 may receive an electrical signal through the second-first and second-third lower contact plugs 241 and 243 connected to the third and fourth source/drain regions 206a and 206b.

One of the second electrode structures 220 may be connected to the second-second lower contact plug 242, and the second electrode structure 220 may receive an electrical signal through the second-second lower contact plug 242 connected to the second circuit element 230b.

The first electrode structure 210 and the second electrode structure 220 may be disposed on the same level as the peripheral interconnection lines 260 and the first peripheral contact plugs 270. In an example, the first-first lower electrodes ML1a of the first electrode structure 210 and the first-second lower electrodes ML1b of the second electrode structure 220 in FIG. 3A may be disposed on the same level as the first peripheral interconnection lines 260a, and may be formed in the same process as the first peripheral interconnection lines 260a. The second-second lower electrodes ML2a of the first electrode structure 210 and the third-second lower electrodes ML2b of the second electrode structure 220 may be disposed on the same level as the second peripheral interconnection lines 260b, and may be formed in the same process as the second peripheral interconnection lines 260b.

The second-first lower electrodes MC2a of the first electrode structure 210 and the third-first lower electrodes MC2b of the second electrode structure 220 of FIG. 3A may be disposed on the same level as the first-first peripheral contact plugs 270a, and may be formed in the same process as the first-first peripheral contact plug 270a. The first-first intermediate electrodes MC3a of the first electrode structure 210 and the second-first intermediate electrodes MC3b of the second electrode structure 220 may be disposed on the same level as the first-second peripheral contact plug 270b, and may be formed in the same process as the first-second peripheral contact plug 270b.

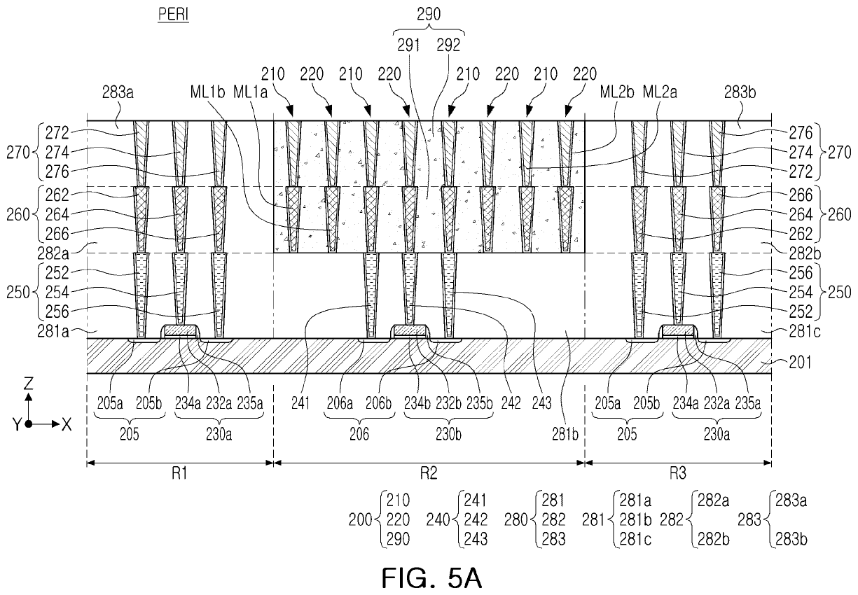

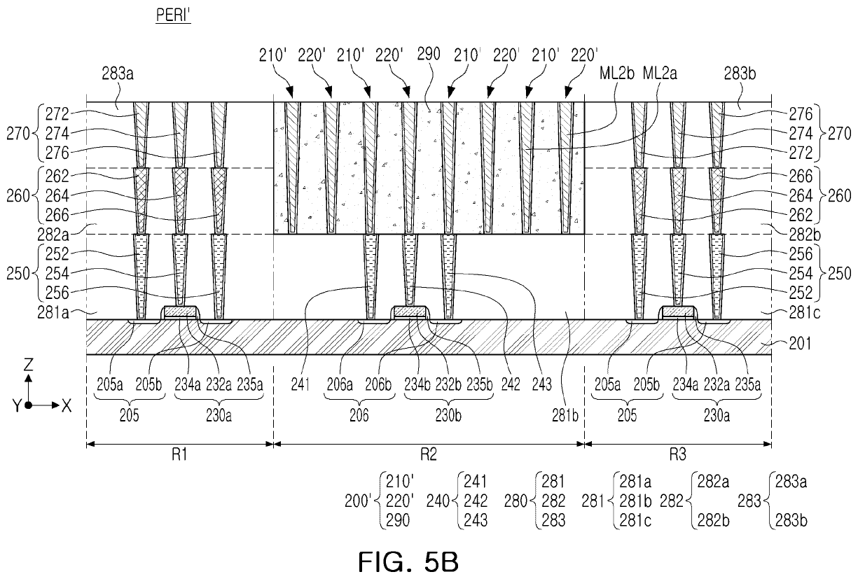

FIG. 5A is a cross-sectional view illustrating an example of a peripheral circuit region of a semiconductor device according to some implementations. In FIG. 5A, the peripheral circuit region PERI of the semiconductor device 10 may include peripheral interconnection structures 250, 260, and 270 disposed in the first and third regions R1 and R3, second lower contact plugs 240 disposed in the second region R2, a capacitor structure 200 on the second lower contact plugs 240, and a peripheral region insulating structure 280 disposed on side surfaces of the peripheral interconnection structures 250, 260, and 270 and side surface of the second lower contact plugs 240.

The peripheral region insulating structure 280 may include a first peripheral insulating layer 281, a second peripheral insulating layer 282, and a third peripheral insulating layer 283. In an example, the first peripheral insulating layer 281 may be disposed on the substrate 201 across the first, second, and third regions R1, R2, and R3 and may be disposed on side surfaces of the first lower contact plugs 250 and the second lower contact plugs 240. The first peripheral insulating layer 281 may include a first-first peripheral insulating layer 281a disposed on the side surfaces of the first lower contact plugs 250 of the first region R1, a first-second peripheral insulating layer 281b disposed on the side surfaces of the second lower contact plugs 240 of the second region R2, and a first-third peripheral insulating layer 281c disposed on the side surfaces of the first lower contact plugs 250 of the third region R3. In an example, an upper surface of the first peripheral insulating layer 281 may be coplanar with an upper surface of the first lower contact plugs 250 and an upper surface of the second lower contact plugs 240.

The first lower contact plugs 250 may be disposed on the same level as the second lower contact plugs 240, and may include the same material. Each of the first lower contact plugs 250 and the second lower contact plugs 240 may include a conductive layer and a barrier layer extending along a bottom surface and a side surface of the conductive layer.

The second peripheral insulating layer 282 may include a second-first peripheral insulating layer 282a disposed on the first-first peripheral insulating layer 281a of the first region R1 and disposed on a side surface of the peripheral interconnection lines 260, and a second-second peripheral insulating layer 282b disposed on the first-third peripheral insulating layer 281c of the third region R3 and disposed on a side surface of the peripheral interconnection lines 260. In an example, the second-first peripheral insulating layer 282a and the second-second peripheral insulating layer 282b may be spaced apart from each other with the capacitor structure 200 interposed therebetween. An upper surface of the second peripheral insulating layer 282 may be coplanar with an upper surface of the peripheral interconnection lines 260. The peripheral interconnection lines 260 may include a conductive layer and a barrier layer extending along a bottom surface and a side surface of the conductive layer.

The first peripheral contact plugs 270 connected to the peripheral interconnection lines 260 may be disposed on the second peripheral insulating layer 282. The first peripheral contact plugs 270 may include a first-first peripheral contact plug 272 on the first-first peripheral interconnection line 262 of the peripheral interconnection line 260, a first-second peripheral contact plug 274 on the first-second peripheral interconnection line 264, and a first-third peripheral contact plug 276 on the first-third peripheral interconnection line 266. The first peripheral contact plugs 270 are illustrated as being disposed on upper surfaces of the first-first peripheral interconnection line 262, the first-second peripheral interconnection line 264 and the first-third peripheral interconnection line 266, respectively, but at least one of the first-first peripheral contact plug 272, the first-second peripheral contact plug 274, or the first-third peripheral contact plug 276 may be omitted.

The third peripheral insulating layer 283 may include a third-first peripheral insulating layer 283a disposed on the second-first peripheral insulating layer 282a of the first region R1 and disposed on a side surface of the first peripheral contact plugs 270, and a third-second peripheral insulating layer 283b disposed on the second-second peripheral insulating layer 282b of the third region R3 and disposed on the side surface of the first peripheral contact plugs 270. In an example, the third-first peripheral insulating layer 283a and the third-second peripheral insulating layer 283b may be spaced apart from each other with the capacitor structure 200 interposed therebetween. An upper surface of the third peripheral insulating layer 283 may be coplanar with an upper surface of the first peripheral contact plugs 270. In the present disclosure, the second peripheral insulating layer 282 and the third peripheral insulating layer 283 may be referred to as a first peripheral dielectric structure.

Since the first, second, and third peripheral insulating layers 281, 282, and 283 include the same material, interlayer interfaces between the first, second, and third peripheral insulating layers 281, 282, and 283 may not be distinguished from each other.

In some implementations, the dielectric capacitor structure 290 may include a first dielectric material having a first dielectric constant, and the peripheral region insulating structure 280 may include a second dielectric material having a second dielectric constant, lower than a first dielectric constant. For example, the dielectric capacitor structure 290 may include a high-κ dielectric material, and the peripheral region insulating structure 280 may include silicon oxide. In another example, the dielectric capacitor structure 290 may include a high-κ material, and the peripheral region insulating structure 280 may include a low-κ material.

In some implementations, the dielectric capacitor structure 290 may include a first dielectric material having a first dielectric constant, the first peripheral insulating layer 281 of the peripheral region insulating structure 280 may include a second dielectric material having a second dielectric constant, lower than a first dielectric constant, and the second peripheral insulating layer 282 and the third peripheral insulating layer 283 may include a third dielectric material having a different third dielectric constant lower than the second dielectric constant. For example, the first dielectric material may include a high-κ dielectric material, the second dielectric material may include silicon oxide, and the third dielectric material may include a low-κ dielectric material.

In some implementations, the second-first peripheral insulating layer 282a and the third-first peripheral insulating layer 283a disposed on side surfaces of the peripheral interconnection lines 260 and the first peripheral contact plugs 270 disposed in the first region R1 may include a second dielectric material having a second dielectric constant, and the second-second peripheral insulating layer 282b and the third-second peripheral insulating layer 283b disposed on side surfaces of the peripheral interconnection lines 260 and the first peripheral contact plugs 270 disposed in the third region R3 may include a third dielectric material having a third dielectric constant lower than the second dielectric constant. For example, the second-first peripheral insulating layer 282a and the third-first peripheral insulating layer 283a may include silicon oxide, and the second-second peripheral insulating layer 282b and the third-second peripheral insulating layer 283b may include a low-κ dielectric material.

The capacitor structure 200 may be disposed on the first-second peripheral insulating layer 281b of the second region R2. The capacitor structure 200 may include first electrode structures 210 and second electrode structures 220 alternating with the first electrode structures 210 in the first direction (X-direction), and a dielectric capacitor structure 290 disposed between the first electrode structures 210 and the second electrode structures 220.

The first-first lower electrodes ML1a of the first electrode structures 210 and the first-second lower electrodes ML1b of the second electrode structures 220 may be alternately disposed in the first direction (X-direction) on the first-second peripheral insulating layer 281b. The second-first lower electrodes MC2a may be disposed on the first-first lower electrodes ML1a of the first electrode structures 210, and the third-first lower electrodes MC2b may be disposed on the first-second lower electrodes ML1b of the second electrode structures 220. The third-first lower electrodes MC2b may be alternately disposed with the second-first lower electrodes MC2a in the first direction (X-direction).

The first-first lower electrodes ML1a and the first-second lower electrodes ML1b may be disposed on the same level as the peripheral interconnection lines 260. The second-first lower electrodes MC2a and the third-first lower electrodes MC2b may be disposed on the same level as the first peripheral contact plugs 270. In an example, each of the first-first lower electrodes ML1a, the second-first lower electrodes MC2a, the first-second lower electrodes ML1b, and the third-first lower electrodes MC2b may include a conductive layer and a barrier layer extending along a side surface and a bottom surface of the conductive layer. The conductive layers of each of the first-second lower electrodes ML1b and the third-first lower electrodes MC2b may include the same material as the conductive layer of the peripheral interconnection lines 260, and the barrier layers of each of the first-second lower electrodes ML1b and the third-first lower electrodes MC2b may include the same material as the barrier layer of the peripheral interconnection lines 260.

The dielectric capacitor structure 290 may include a first capacitor dielectric layer 291 disposed on side surfaces of the first-first lower electrodes ML1a of the first electrode structures 210 and side surfaces of the first-second lower electrodes ML1b of the second electrode structures 220, and a second capacitor dielectric layer 292 disposed on the first capacitor dielectric layer 291 and disposed on side surfaces of the second-first lower electrodes MC2a of the first electrode structures 210 and side surfaces of the third-first lower electrodes MC2b of the second electrode structures 220. The first capacitor dielectric layer 291 may be disposed between the first-first lower electrodes ML1a and the first-second lower electrodes ML1b, and the second capacitor dielectric layer 292 may be disposed between the second-first lower electrodes MC2a and the third-first lower electrodes MC2b. In an example, a lower surface of the dielectric capacitor structure 290 may be in contact with the first-second peripheral insulating layer 281b, and a side surface of the dielectric capacitor structure 290 may be in contact with the second peripheral insulating layer 282 and the third peripheral insulating layer 283.

FIG. 5B is a cross-sectional view illustrating an example of a peripheral circuit region of a semiconductor device according to some implementations. In FIG. 5B, the remaining components, excluding a capacitor structure 200′ of the peripheral circuit region PERI', may be identical to or may correspond to the components illustrated in FIG. 5A. Duplicate descriptions of the identical or corresponding components will be omitted. The capacitor structure 200′ of FIG. 5B may correspond to the capacitor structure 200′ of FIG. 3B.

The capacitor structure 200′ may be disposed on the first-second peripheral insulating layer 281b of the second region R2. The capacitor structure 200′ may include first electrode structures 210′ and second electrode structures 220′ alternating with the first electrode structures 210′ in the first direction (X-direction), and a dielectric capacitor structure 290 disposed between the first electrode structures 210′ and the second electrode structures 220′.

The first portions MLa of the first electrode structures 210′ and the second portions MLb of the second electrode structures 220′ may be disposed alternately in the first direction (X-direction) on the first-second peripheral insulating layer 281b. Each of the first portions MLa and the second portions MLb may overlap the second peripheral insulating layer 282 and the third peripheral insulating layer 283 in a horizontal direction, and may have a width that narrows toward a lower portion. Each of the first portions MLa and the second portions MLb may include a conductive layer and a barrier layer extending to a bottom surface and a side surface of the conductive layer. In an example, lower surfaces of each of the first portions MLa of the first electrode structures 210′ and the second portions MLb of the second electrode structures 220′ may be coplanar with lower surfaces of the peripheral interconnection lines 260, and upper surfaces of each of the first portions MLa of the first electrode structures 210′ and the second portions MLb of the second electrode structures 220′ may be coplanar with upper surfaces of the first peripheral contact plugs 270.

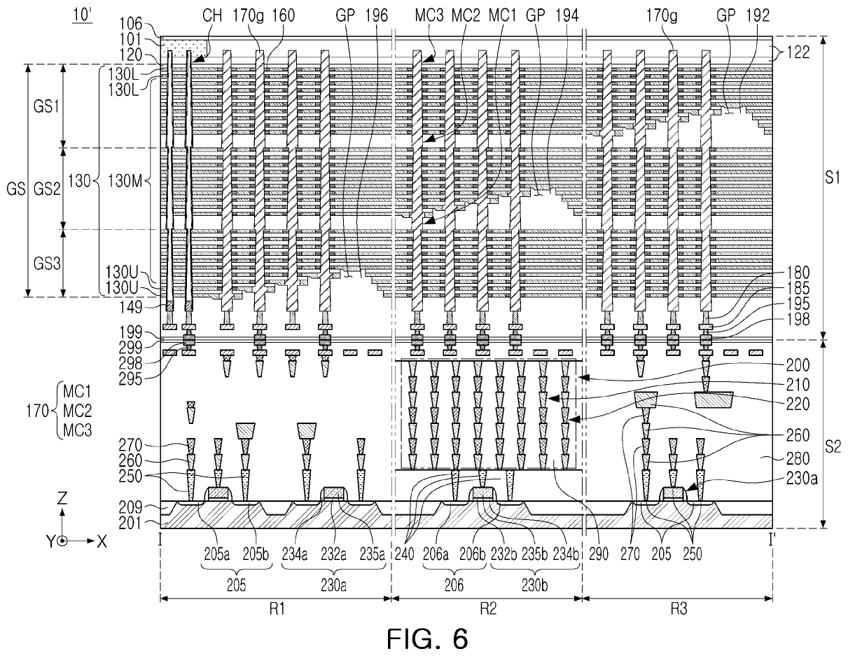

FIG. 6 is a cross-sectional view taken along line I-I′ of the semiconductor device of FIG. 2A according to some implementations. In FIG. 6, a semiconductor device 10′ may include a memory cell structure S1 and a peripheral circuit structure S2 bonded by a wafer bonding method.

The description of the peripheral circuit region PERI described above with reference to FIG. 2B may be applied to the peripheral circuit structure S2. However, the peripheral circuit structure S2 may further include second bonding vias 295, second bonding metal layers 298, and a second bonding insulating layer 299, which are bonding structures. The second bonding vias 295 may be connected to uppermost interconnections, among the peripheral interconnection lines 260. At least a portion of the second bonding metal layer 298 may be connected to the second bonding vias 295. The second bonding metal layer 298 may be connected to first bonding metal layers 198 of the memory cell structure S1. The second bonding metal layers 298 may provide an electrical connection path according to the bonding of the memory cell structure S1 and the peripheral circuit structure S2 together with the first bonding metal layers 198. In another example, some of the second bonding metal layers 298 may not be connected to lines of a lower portion and may be disposed only for bonding.

The second bonding vias 295 and the second bonding metal layers 298 may include a conductive material, for example, copper (Cu). The second bonding insulating layer 299 may be disposed around the second bonding metal layers 298. The second bonding insulating layer 299 may also function as a diffusion barrier layer of the second bonding metal layers 298, and may include, for example, at least one of SiN, SiON, SiCN, SiOC, SiOCN, or SiO.

For the memory cell structure S1, the description of the memory cell region CELL described above with reference to FIG. 2B may be applied. The memory cell structure S1 may further include a substrate insulating layer 122, cell interconnection lines 185, first bonding vias 195, first bonding metal layers 198, and a first bonding insulating layer 199 included in the bonding structure. In an example, the memory cell structure S1 may further include a passivation layer 106 covering the upper surface of the plate layer 101 and an upper surface of the substrate insulating layers 121.

The substrate insulating layer 122 may be disposed below the gate structure GS, may be disposed between the plate layer 101 and the gate structure GS on the first memory region CA1 of FIG. 2A, and may be disposed on the same level as the plate layer 101 on the second memory region CA2. The channel structure CH may penetrate through the gate structure GS and the substrate insulating layer 122 in the first memory region CA1 and may be disposed in the plate layer 101. The substrate insulating layer 122 may be disposed on the plate layer 101 on the first memory region CA1, and may be disposed on the same level as the plate layer 101 on the second memory region CA2.

The cell interconnection lines 185 may be connected to the studs 180. However, in some implementations, the number of layers and the arrangement form of the plugs and the interconnection lines included in the cell interconnection structure may be variously changed. The cell interconnection lines 185 may be formed of a conductive material, and may include, for example, at least one of tungsten (W), aluminum (Al), or copper (Cu).

The first bonding vias 195 and the first bonding metal layers 198 may be arranged below cell interconnection lines 185 in a lowermost portion. The first bonding vias 195 may connect the cell interconnection lines 185 and the first bonding metal layers 198, and the first bonding metal layers 198 may be bonded to the second bonding metal layers 298 of the peripheral circuit structure S2. The first bonding insulating layer 199 may be bonded and connected to the second bonding insulating layer 299 of the peripheral circuit structure S2. The first bonding vias 195 and the first bonding metal layers 198 may include a conductive material, for example, copper (Cu). The first bonding insulating layer 199 may include, for example, at least one of SiO, SiN, SiCN, SiOC, SiON, and SiOCN.

The first and second semiconductor structures S1 and S2 may be bonded by bonding of the first bonding metal layers 198 and the second bonding metal layers 298 and bonding of the first bonding insulating layer 199 and the second bonding insulating layer 299. The bonding of the first bonding metal layers 198 and the second bonding metal layers 298 may be, for example, copper (Cu)-copper (Cu) bonding, and the bonding of the first bonding insulating layer 199 and the second bonding insulating layer 299 may be, for example, dielectric-dielectric bonding, such as SiCN—SiCN bonding. The first and second semiconductor structures S1 and S2 may be bonded to each other by hybrid bonding including copper (Cu)-copper (Cu) bonding and dielectric-dielectric bonding.

The passivation layer 106 may be disposed on the upper surface of the plate layer 101 and may protect a semiconductor device 10′. The passivation layer 106 may include an insulating material, for example, at least one of silicon oxide, silicon nitride, or silicon carbide. The substrate insulating layer 121 may be widely disposed in the first region R1 and the second region R2 so as to cover upper ends of the contact plugs 170, upper ends of through-plugs 164, and upper ends of capacitor contacts 165. However, in some implementations, an arrangement shape of the substrate insulating layer 121 may be variously changed in a range of electrically separating the contact plugs 170, the through-plugs 164, and the capacitor contacts 165 from the plate layer 101.

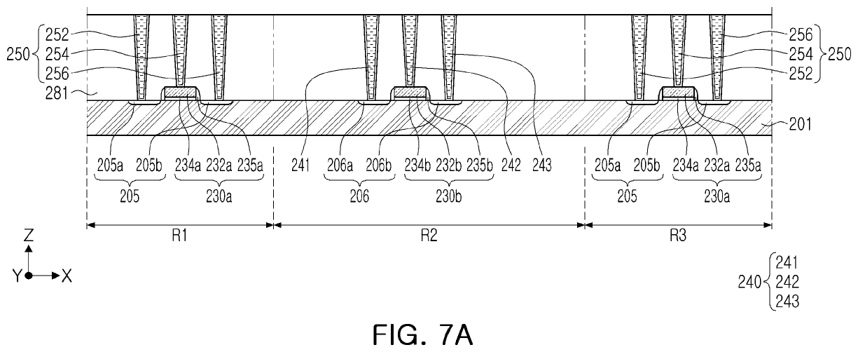

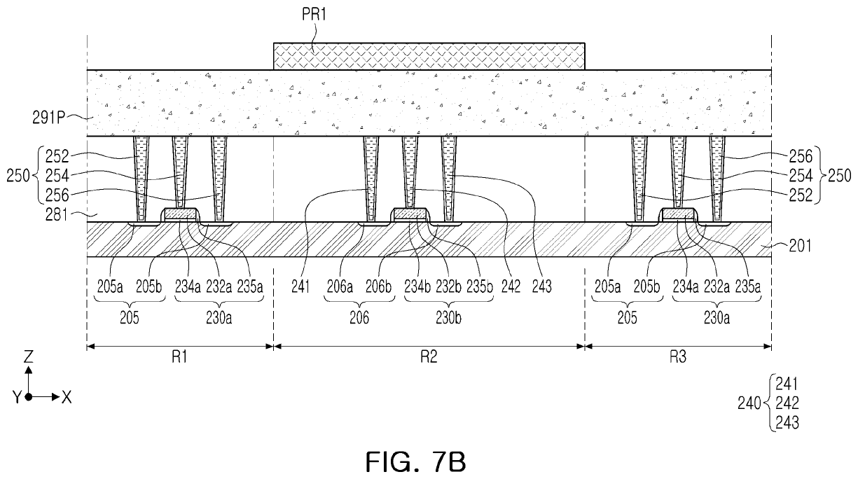

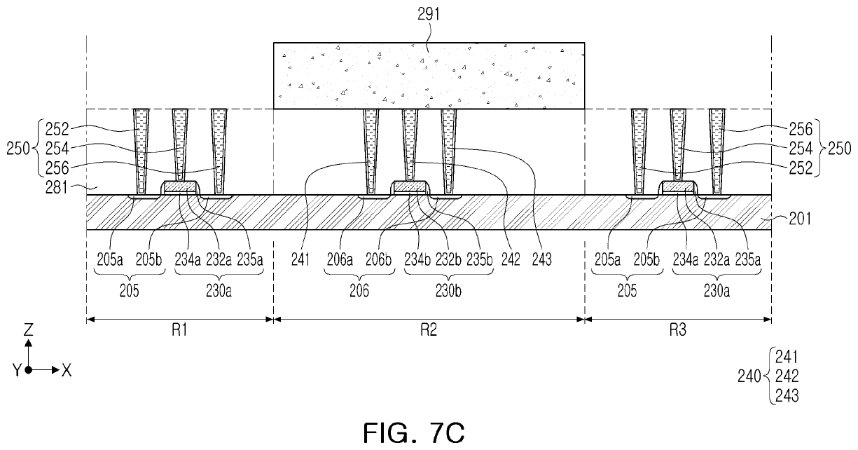

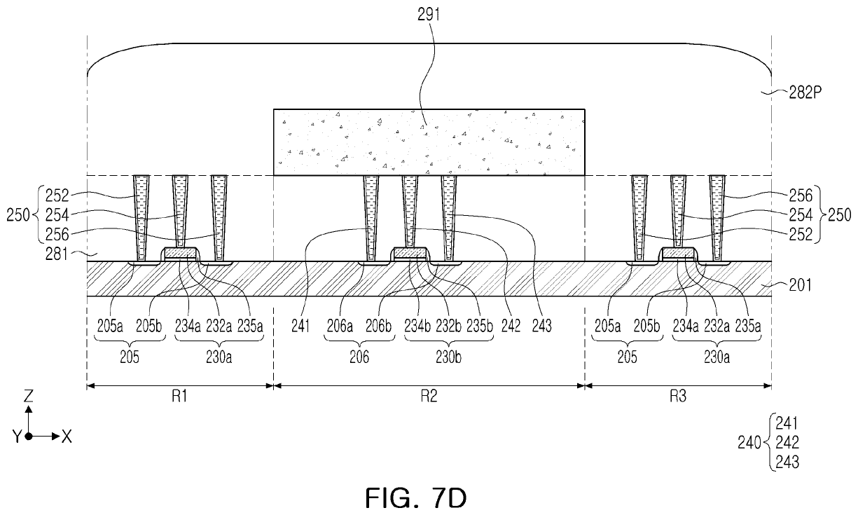

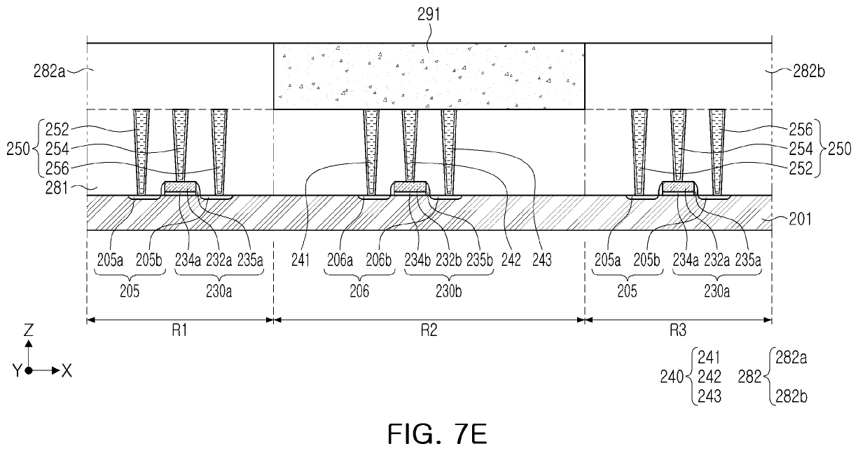

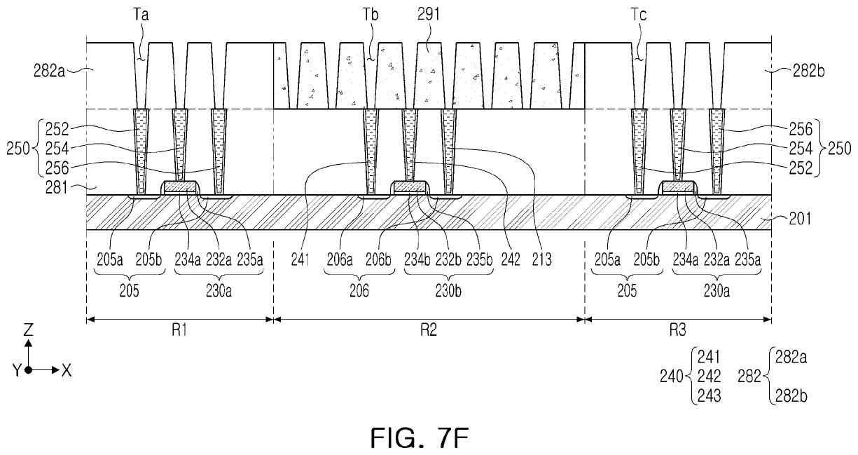

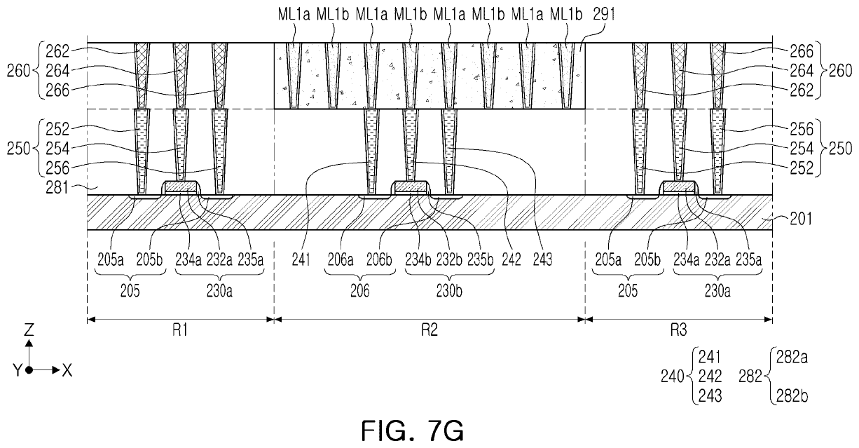

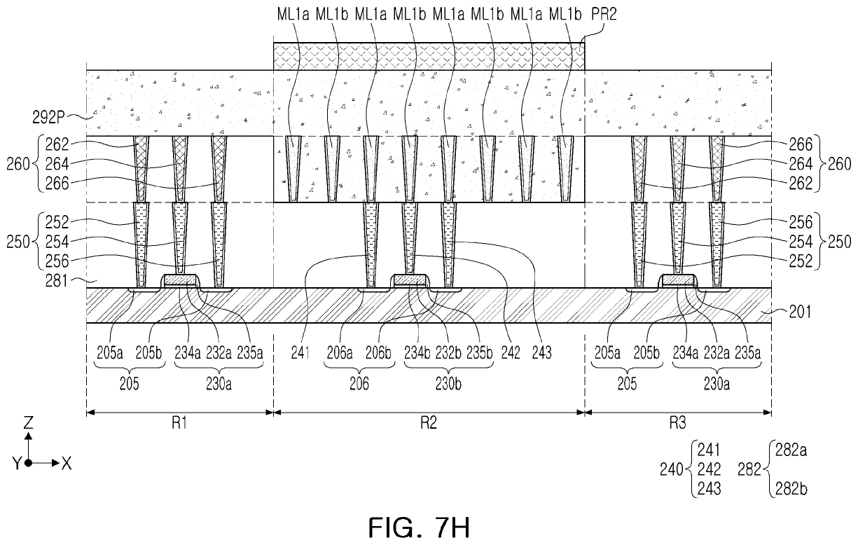

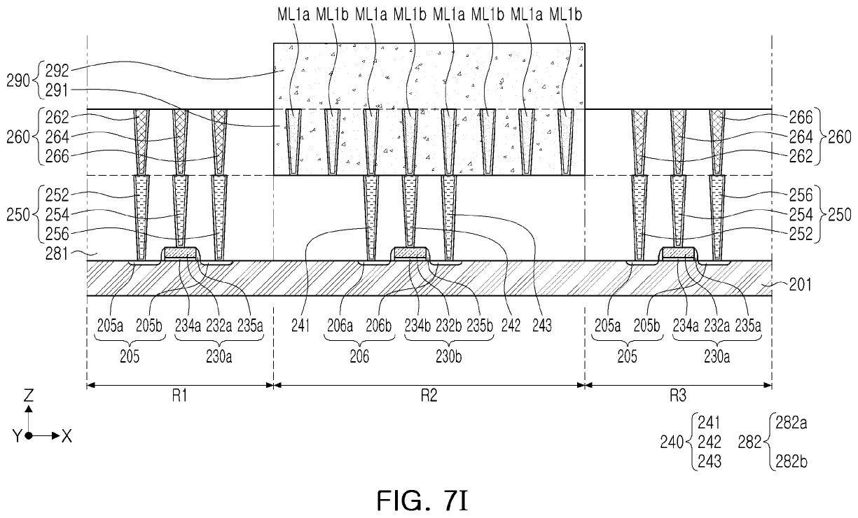

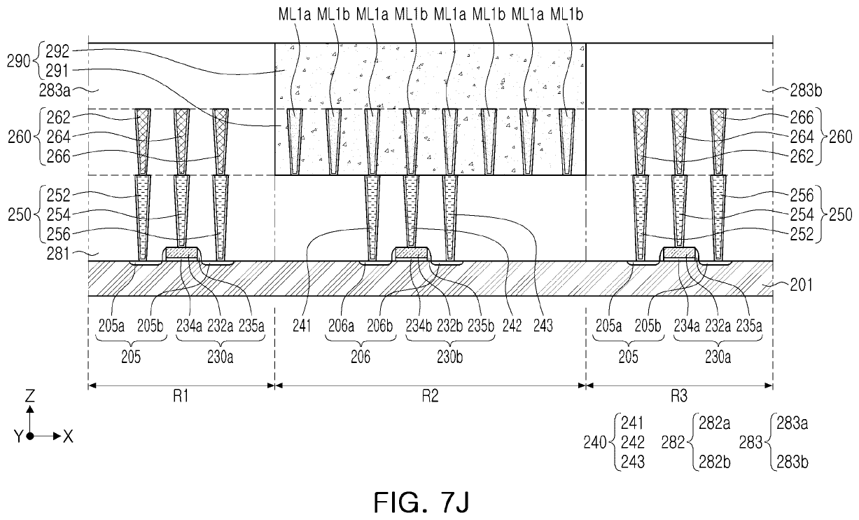

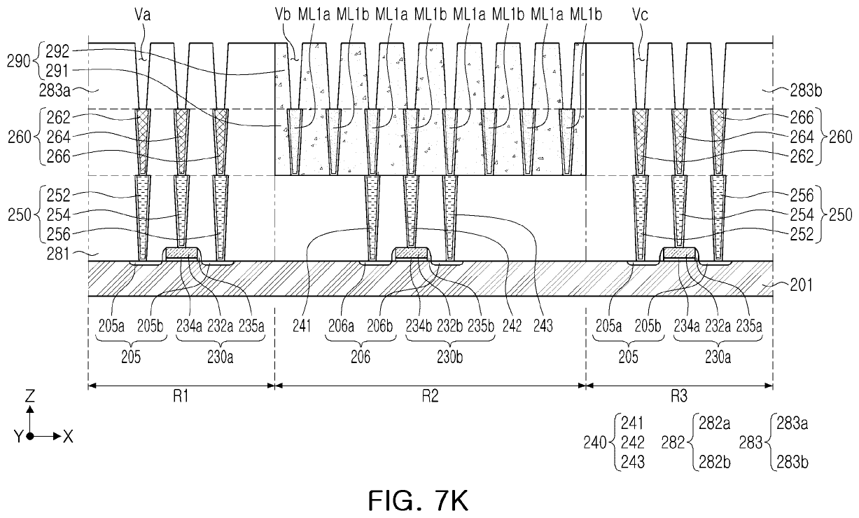

FIGS. 7A to 7K are views illustrating an example of a method of manufacturing a semiconductor device according to some implementations. In FIG. 7A, a method of manufacturing a semiconductor device may include an operation of forming a first peripheral insulating layer 281 on a substrate 201, forming first lower contact plugs 250 penetrating through the first peripheral insulating layer 281 disposed on the first and third regions R1 and R3 of the substrate 201, and forming second lower contact plugs 240 penetrating through the first peripheral insulating layer 281 disposed on the second region R2 of the substrate 201. After forming the first peripheral insulating layer 281 on the substrate 201, first etching holes may be formed through an etching process of exposing upper surfaces of first impurity regions 205 of the first and third regions R1 and R3 and upper surfaces of first circuit elements 230a, and then a barrier layer and a conductive layer are formed in the first etching holes, thereby forming first lower contact plugs 250.

After forming a first peripheral insulating layer 281 on the substrate 201, second etching holes may be formed through an etching process of exposing upper surfaces of second impurity regions 206 of the second region R2 and upper surfaces of second circuit elements 230b, and then a barrier layer and a conductive layer may be formed in the second etching holes, thereby forming second lower contact plugs 240.

In FIG. 7B, a first preliminary capacitor dielectric layer 291P may be formed on the first peripheral insulating layer 281, and a first photoresist pattern PR1 may be formed on the first preliminary capacitor dielectric layer 291P overlapping the second region R2. The first preliminary capacitor dielectric layer 291P may be formed on the substrate 201 over the first, second, and third regions R1, R2 and R3. The first preliminary capacitor dielectric layer 291P includes a dielectric material having a high dielectric constant, and may have a higher dielectric constant than a dielectric material of the first peripheral insulating layer 281.

In FIG. 7C, the first photoresist pattern PR1 may be used as a mask to remove the first preliminary capacitor dielectric layer 291P on the first and third regions R1 and R3, thereby forming the first capacitor dielectric layer 291 remaining on the second region R2.

In FIG. 7D, a second preliminary peripheral insulating layer 282P may be formed on the first peripheral insulating layer 281 exposed on the first and third regions R1 and R3 and the first capacitor dielectric layer 291 exposed on the second region R2. The second preliminary peripheral insulating layer 282P may include the same dielectric material (or insulating material) as the first peripheral insulating layer 281.

In FIG. 7E, a planarization process may be performed on the second preliminary peripheral insulating layer 282P so as to expose an upper surface of the first capacitor dielectric layer 291, thereby forming a second peripheral insulating layer 282 including a second-first peripheral insulating layer 282a and a second-second peripheral insulating layer 282b. The planarization process may include an etch back or a chemical mechanical polishing (CMP) process. The second-first peripheral insulating layer 282a may be formed on the first peripheral insulating layer 281 of the first region R1, and the second-second peripheral insulating layer 282b may be formed on the first peripheral insulating layer 281 of the third region R3. An upper surface of the second-first peripheral insulating layer 282a and an upper surface of the second-second peripheral insulating layer 282b may be coplanar with an upper surface of the first capacitor dielectric layer 291. The second peripheral insulating layer 282 may surround a side surface of the first capacitor dielectric layer 291.

In FIG. 7F, first trenches Ta penetrating through the second-first peripheral insulating layer 282a and exposing the upper surfaces of the first lower contact plugs 250 may be formed in the first region R1, third trenches Tc penetrating through the second-second peripheral insulating layer 282b and exposing the upper surfaces of the first lower contact plugs 250 may be formed in the third region R3, and second trenches Tb penetrating through the first capacitor dielectric layer 291 and exposing the upper surfaces of the second lower contact plugs 240 and a portion of the upper surface of the first peripheral insulating layer 281 may be formed in the second region R2. In an example, the first trench Ta, the second trench Tb and the third trench Tc may extend in the second direction (Y-direction).

In FIG. 7G, peripheral interconnection lines 260 may be formed by forming a barrier layer and a conductive layer in the first trenches Ta and the third trenches Tc in the first and third regions R1 and R3, and first-first lower electrodes ML1a and first-second lower electrodes ML1b alternating with the first-first lower electrodes ML1a in the first direction (X-direction) may be formed by forming a barrier layer and a conductive layer in the second trenches Tb of the second region R2. Some of the first-first lower electrodes ML1a may overlap the second-first and second-third lower contact plugs 241 and 243, and some of the first-second lower electrodes ML1b may overlap the second-second lower contact plug 242.

In FIG. 7H, a second preliminary capacitor dielectric layer 292P may be formed on the second peripheral insulating layer 282 and the first capacitor dielectric layer 291, and a second photoresist pattern PR2 may be formed on the second preliminary capacitor dielectric layer 292P overlapping the second region R2. The second preliminary capacitor dielectric layer 292P may be formed on the substrate 201 over the first, second, and third regions R1, R2, and R3. The second preliminary capacitor dielectric layer 292P includes a dielectric material having a high dielectric constant, and may have a higher dielectric constant than the dielectric material of the first peripheral insulating layer 281 and the second peripheral insulating layer 282. The second preliminary capacitor dielectric layer 292P may include the same dielectric material as the first capacitor dielectric layer 291.

In FIG. 7I, the second photoresist pattern PR2 may be used as a mask to remove the second preliminary capacitor dielectric layer 292P on the first and third regions R1 and R3, thereby forming the second capacitor dielectric layer 292 remaining on the second region R2. The second capacitor dielectric layer 292 may be formed on the first capacitor dielectric layer 291 and may be included in a dielectric capacitor structure 290.

In FIG. 7J, a third peripheral insulating layer 283 may be formed on the second peripheral insulating layer 282 in the first and third regions R1 and R3. An operation of forming the third peripheral insulating layer 283 may include an operation of forming a third preliminary peripheral insulating layer on the second peripheral insulating layer 282 exposed on the first and third regions R1 and R3 and the second capacitor dielectric layer 292 exposed on the second region R2, and performing a planarization process on the third preliminary peripheral insulating layer so as to an upper surface of the second capacitor dielectric layer 292. The third peripheral insulating layer 283 may include the same dielectric material (or insulating material) as the second peripheral insulating layer 282.

The third-first peripheral insulating layer 283a may be formed on the second-first peripheral insulating layer 282a of the first region R1, and the third-second peripheral insulating layer 283b may be formed on the second-second peripheral insulating layer 282b of the third region R3. An upper surface of the third-first peripheral insulating layer 283a and an upper surface of the third-second peripheral insulating layer 283b may be coplanar with an upper surface of the second capacitor dielectric layer 292. The third peripheral insulating layer 283 may surround a side surface of the second capacitor dielectric layer 292.

In FIG. 7K, first via holes Va penetrating through the third-first peripheral insulating layer 283a and exposing upper surfaces of the peripheral interconnection lines 260 may be formed in the first region R1, third via holes Vc penetrating through the third-second peripheral insulating layer 283b and exposing the upper surfaces of the peripheral interconnection lines 260 may be formed in the third region R3, and second via holes Vb penetrating through the second capacitor dielectric layer 292 and exposing upper surfaces of the first-first lower electrodes ML1a and a portion of upper surfaces of the first-second lower electrodes ML1b may be formed in the second region R2. Each of the first via holes Va and the third via holes Vc may have a pillar shape. Each of the second via holes Vb may extend in the second direction (Y-direction).

Next, in FIG. 7K and FIG. 5A, first peripheral contact plugs 270 may be formed by forming a barrier layer and a conductive layer in the first via holes Va and the third via holes Vc in the first and third regions R1 and R3, and second-first lower electrodes MC2a overlapping the first-first lower electrodes ML1a and third-first lower electrodes MC2b overlapping the first-second lower electrodes ML1b may be formed by forming a barrier layer and a conductive layer in the second via holes Vb of the second region R2. A peripheral circuit region PERI of the semiconductor device 10 may be formed by repeating the process according to FIG. 7B to FIG. 7K. Next, in FIG. 2B, the semiconductor device 10 may be manufactured by forming a memory cell region CELL on the peripheral circuit region PERI.

In some implementations, a method for manufacturing a semiconductor device may form a dielectric capacitor structure 290 covering first electrode structures 210 and second electrode structures 220 that are partially arranged alternately in a plate shape in the peripheral circuit region PERI, and the dielectric capacitor structure 290 may have a higher dielectric constant than the peripheral region insulating structure 280 surrounding the peripheral interconnection structures 250, 260 and 270, thereby manufacturing the semiconductor device 10 including a capacitor structure 200 having improved electrical characteristics.

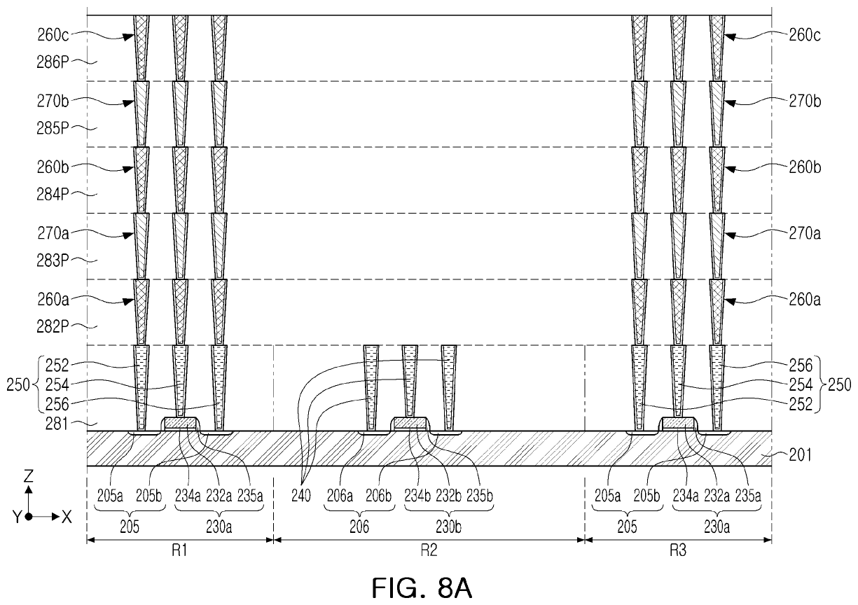

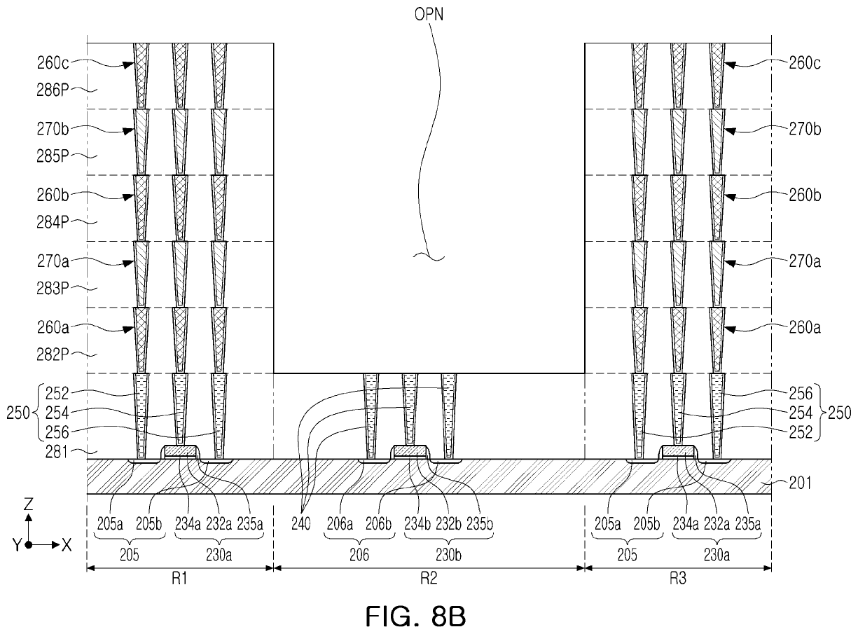

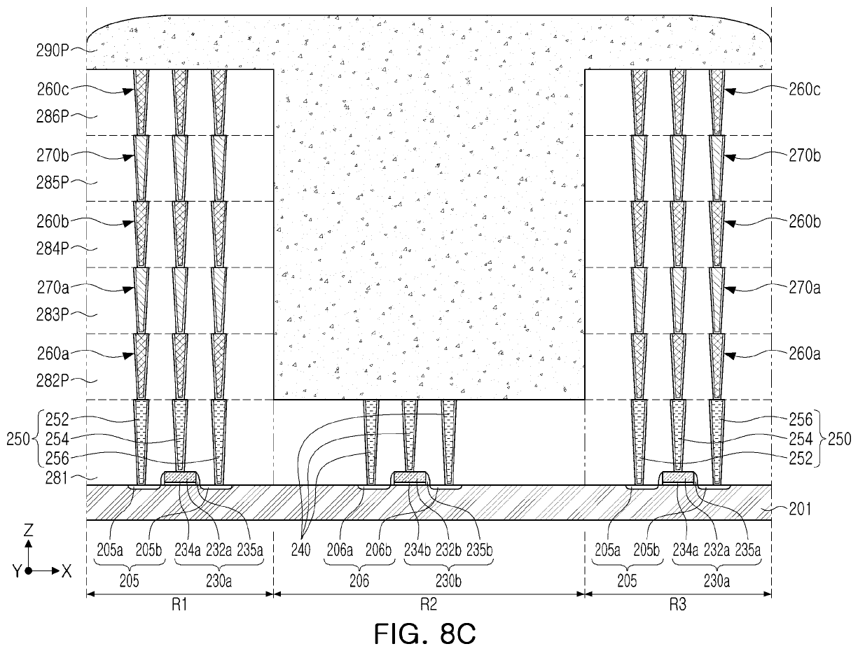

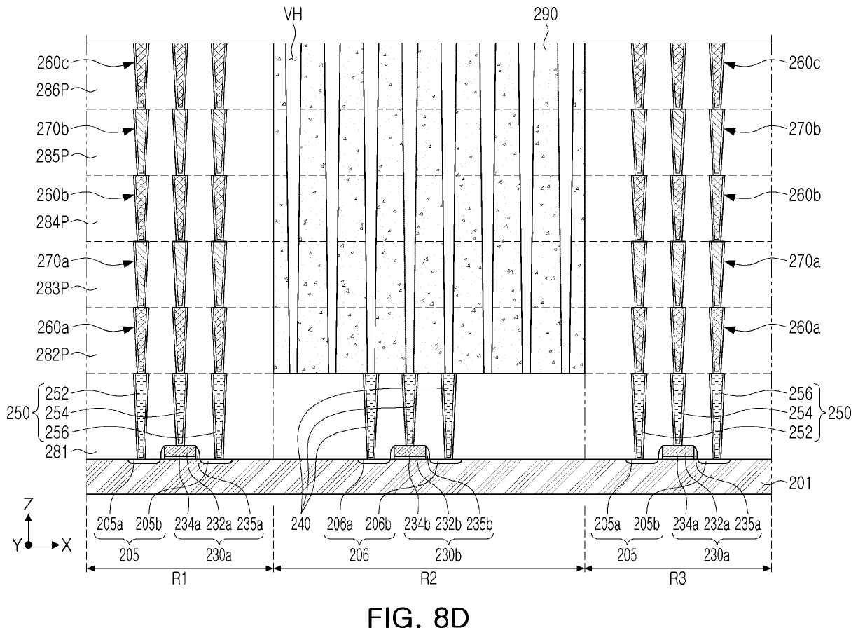

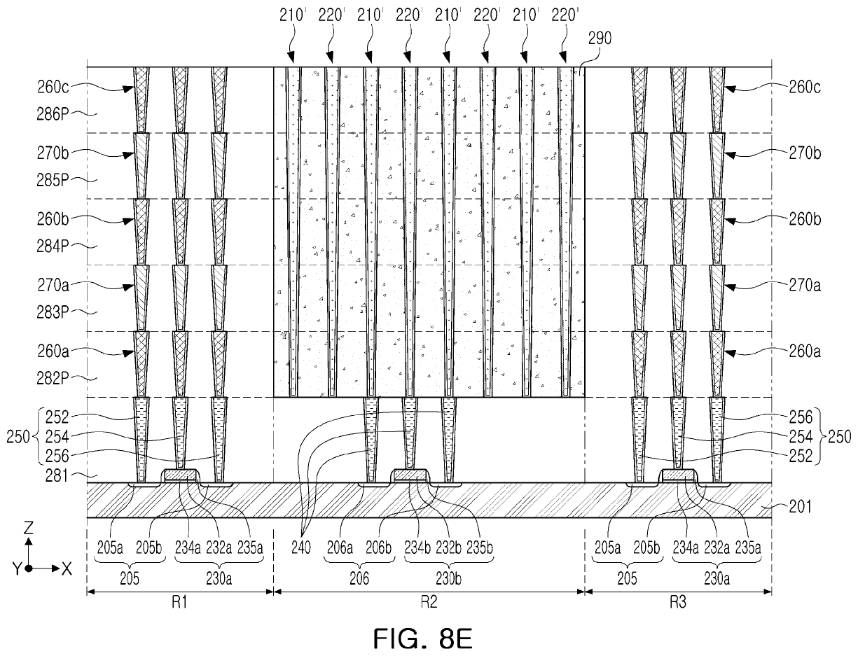

FIGS. 8A to 8E are views illustrating an example of a method of manufacturing a semiconductor device according to some implementations. In FIGS. 8A to 8E, a method of forming a peripheral circuit region PERI including the capacitor structure 200′ of FIG. 3B will be described.

In FIG. 8A, a method of forming a peripheral circuit region PERI may include an operation of forming a first peripheral insulating layer 281 on a substrate 201, forming first lower contact plugs 250 penetrating through the first peripheral insulating layer 281 disposed on the first and third regions R1 and R3 of the substrate 201, and forming second lower contact plugs 240 penetrating through the first peripheral insulating layer 281 disposed on the second region R2 of the substrate 201.

In the first and third regions R1 and R3, peripheral interconnection lines 260a, 260b, and 260c and first peripheral contact plugs 270a and 270b disposed on different levels from the peripheral interconnection lines 260a, 260b, and 260c may be formed on the first lower contact plugs 250.

After forming a second preliminary peripheral insulating layer 282P on the first peripheral insulating layer 281, etching holes may be formed so that the upper surfaces of the first lower contact plugs 250 may be exposed in the first and third regions R1 and R3, and then, a barrier layer and a conductive layer may be formed in the etching holes, thereby forming first peripheral interconnection lines 260a.

After forming a third preliminary peripheral insulating layer 283P on the second preliminary peripheral insulating layer 282P, etching holes may be formed so that upper surfaces of the first peripheral interconnection lines 260a may be exposed in the first and third regions R1 and R3, and then a barrier layer and a conductive layer may be formed in the etching holes, thereby forming first-first peripheral contact plugs 270a.

After forming a fourth preliminary peripheral insulating layer 284P on the third preliminary peripheral insulating layer 283P, etching holes may be formed so that upper surfaces of the first-first peripheral contact plugs 270a may be exposed in the first and third regions R1 and R3, and then a barrier layer and a conductive layer may be formed in the etching holes, thereby forming second peripheral interconnection lines 260b.

After forming a fifth preliminary peripheral insulating layer 285P on the fourth preliminary peripheral insulating layer 284P, an etching hole may be formed so that upper surfaces of the second peripheral interconnection lines 260b may be exposed in the first and third regions R1 and R3, and then a barrier layer and a conductive layer may be formed in the etching hole, thereby forming first-second peripheral contact plugs 270b.

After forming a sixth preliminary peripheral insulating layer 286P on the fifth preliminary peripheral insulating layer 285P, an etching hole may be formed so that upper surfaces of the first-second peripheral contact plugs 270b may be exposed in the first and third regions R1 and R3, and then a barrier layer and a conductive layer may be formed in the etching hole, thereby forming third peripheral interconnection lines 260c.

In FIG. 8B, the second to sixth preliminary peripheral insulating layers 282P to 286P overlapping the first peripheral insulating layer 281 in the second region R2 may be removed to form an opening hole OPN exposing the upper surface of the first peripheral insulating layer 281 of the second region R2.

In FIG. 8C, a preliminary capacitor dielectric layer 290P may be formed to cover the first, second, and third regions R1, R2, and R3 of the substrate 201. The preliminary capacitor dielectric layer 290P may be formed on an upper surface of the sixth preliminary peripheral insulating layer 286P on the first and third regions R1 and R3, and may fill the inside of the opening hole OPN formed in the second region R2. The preliminary capacitor dielectric layer 290P may include a dielectric material having a high dielectric constant. In an example, the preliminary capacitor dielectric layer 290P may have a dielectric constant higher than dielectric constants of the first peripheral insulating layer 281 and the second to sixth preliminary peripheral insulating layers 282P to 286P.

In FIG. 8D, a planarization process may be performed on the preliminary capacitor dielectric layer 290P so as to expose the upper surface of the sixth preliminary peripheral insulating layer 286P and an upper surface of the third peripheral wirings 260c on the first and third regions R1 and R3, thereby forming a dielectric capacitor structure 290. In the second region R2, capacitor holes VH may be formed so that a portion of the upper surface of the first peripheral insulating layer 281 and the upper surface of the second lower contact plugs 240 may be exposed and may be spaced apart in the first direction (X-direction). The capacitor holes VH may be formed through a high aspect ratio contact (HARC) etching process, and may extend in the second direction (Y-direction) and the vertical direction (Z-direction).

In FIG. 8E, first and second electrode structures 210′ and 220′ alternating in the first direction (X-direction) and surrounded by a dielectric capacitor structure 290 may be formed by forming a barrier layer and a conductive layer in the capacitor holes VH. Accordingly, a peripheral circuit region PERI including the capacitor structure 200′ of FIG. 3B may be formed.

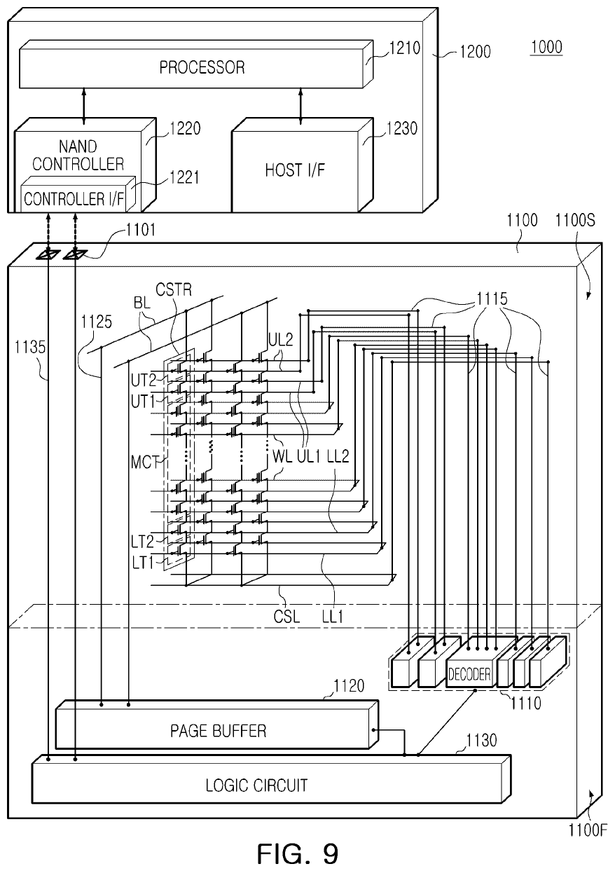

FIG. 9 is a view schematically illustrating an example of a data storage system including a semiconductor device according to some implementations. In FIG. 9, a data storage system 1000 may include a semiconductor device 1100 and a controller 1200 electrically connected to the semiconductor device 1100. The data storage system 1000 may be a storage device including one or a plurality of semiconductor devices 1100 or an electronic device including a storage device. For example, the data storage system 1000 may be a solid state drive device (SSD), a Universal Serial Bus (USB), a computing system, a medical device, or a communication device, including one or a plurality of semiconductor devices 1100.

The semiconductor device 1100 may be a nonvolatile memory device, for example, a NAND flash memory device, as described above with reference to FIGS. 1A to 2C. The semiconductor device 1100 may include a first structure 1100F and a second structure 1100S on the first structure 1100F. In some implementations, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each memory cell string CSTR may include lower transistors LT1 and LT2 adjacent to a common source line CSL, upper transistors UT1 and UT2 adjacent to a bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example embodiments.

In some implementations, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some implementations, the lower transistors LT1 and LT2 may include a lower erase control transistor LT1 and a ground select transistor LT2 serially connected. The upper transistors UT1 and UT2 may include a string select transistor UT1 and an upper erase control transistor UT2 serially connected. At least one of the lower erase control transistor LT1 and the upper erase control transistor UT2 may be used for an erase operation of erasing data stored in the memory cell transistors MCT by utilizing the GIDL phenomenon.

The common source line CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second interconnection lines 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection line 1135 extending from the first structure 1100F to the second structure 1100S.

The controller 1200 may include a processor 1210, a NAND controller 1220, and a host interface 1230. According to some implementations, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a controller interface 1221 processing communication with the semiconductor device 1100. Through the controller interface 1221, a control command for controlling the semiconductor device 1100, data to be written to the memory cell transistors MCT of the semiconductor device 1100, data to be read from the memory cell transistors MCT of the semiconductor device 1100, and the like, may be transmitted. The host interface 1230 may provide a communication function between the data storage system 1000 and an external host. When receiving the control command from the external host through the host interface 1230, the processor 1210 may control the semiconductor device 1100 in response to the control command.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
a first semiconductor structure including a substrate having a first region and a second region, a first interconnection structure on the first region of the substrate, and a capacitor structure on the second region of the substrate; and
a second semiconductor structure including memory cells overlapping the first semiconductor structure in a vertical direction,
wherein the first interconnection structure includes
at least one peripheral interconnection line,
at least one peripheral contact plug disposed on a different level from a level of the at least one peripheral interconnection line, and
a first peripheral dielectric structure on a side surface of the at least one peripheral interconnection line and a side surface of the at least one peripheral contact plug, and
wherein the capacitor structure includes
a first electrode structure including first portions spaced apart from each other in a first direction and extending in a second direction and the vertical direction,
a second electrode structure including second portions alternately arranged with the first portions in the first direction and extending in the second direction and the vertical direction, and
a dielectric capacitor structure between the first portions of the first electrode structure and the second portions of the second electrode structure,
wherein the first direction is parallel to an upper surface of the substrate, the second direction is parallel to the upper surface of the substrate and intersects the first direction, and the vertical direction is perpendicular to the upper surface of the substrate and intersects the first direction and the second direction,
wherein each of the first portions includes a first lower electrode and a first intermediate electrode overlapping the first lower electrode in the vertical direction,
wherein each of the second portions includes a second lower electrode and a second intermediate electrode overlapping the second lower electrode in the vertical direction,
wherein the first lower electrode and second lower electrode are disposed on a same level as a first peripheral interconnection line of the at least one peripheral interconnection line,
wherein the first intermediate electrode and second intermediate electrode are disposed on a same level as a first peripheral contact plug of the at least one peripheral contact plug,
wherein the dielectric capacitor structure includes a first dielectric material having a first dielectric constant, and
wherein the first peripheral dielectric structure includes a second dielectric material having a second dielectric constant lower than the first dielectric constant.

2. The semiconductor device of claim 1, wherein an upper surface of the first peripheral dielectric structure is coplanar with an upper surface of the dielectric capacitor structure.

3. The semiconductor device of claim 1, further comprising:
a first circuit element on the first region of the substrate;
a second circuit element on the second region of the substrate;
a first lower contact plug connected to the first circuit element;
a second lower contact plug connected to the second circuit element; and
a first insulating layer covering side surfaces of the first lower contact plugs and side surfaces of the second lower contact plugs,
wherein the first interconnection structure and the capacitor structure are on the first insulating layer.

4. The semiconductor device of claim 3, wherein the first insulating layer includes a same dielectric material as the second dielectric material of the first peripheral dielectric structure.

5. The semiconductor device of claim 3, wherein the first lower contact plugs are disposed on a same level as the second lower contact plugs.

6. The semiconductor device of claim 3,
wherein a lower surface of the dielectric capacitor structure is in contact with the first insulating layer, and
wherein a side surface of the dielectric capacitor structure is in contact with the first peripheral dielectric structure.

7. The semiconductor device of claim 3,
wherein the first circuit element includes a first gate structure and a first impurity region in the substrate on sides of the gate structure,
wherein the first lower contact plugs include a first contact plug connected to the gate structure and a second contact plug connected to the first impurity region,
wherein the first contact plug is connected to one of the first portions, and
wherein the second contact plug is connected to one of the second portions.

8. The semiconductor device of claim 1,
wherein the first electrode structure includes a first strap portion extending in the first direction,
wherein the second electrode structure includes a second strap portion extending in the first direction,
wherein the first portions of the first electrode structure extend from the first strap portion, and
wherein the second portions of the second electrode structure extend from the second strap portion.

9. The semiconductor device of claim 1,
wherein the first semiconductor structure includes a third interconnection structure, and
wherein the third interconnection structure includes:
a second peripheral interconnection line;
a second peripheral contact plug on the second peripheral interconnection line; and
a second peripheral dielectric structure on a side surface of the second peripheral wiring and a side surface of the second peripheral contact plug,
wherein the second peripheral interconnection line is on a same level as the first peripheral interconnection line,
wherein the second peripheral contact plug is on a same level as the first peripheral contact plug, and
wherein the second peripheral dielectric structure includes a third dielectric material having a third dielectric constant lower than the second dielectric constant of the first peripheral dielectric structure.

10. The semiconductor device of claim 1, wherein a side surface of the dielectric capacitor structure is surrounded by a side surface of the first peripheral dielectric structure.

11. The semiconductor device of claim 1,
wherein the first lower electrode and the second lower electrode of the capacitor structure include a first conductive layer and a first barrier layer covering a bottom surface and a side surface of the first conductive layer,
wherein the first peripheral interconnection line of the first interconnection structure includes a second conductive layer and a second barrier layer covering a bottom surface and a side surface of the second conductive layer,
wherein the first conductive layer and the second conductive layer include a same first conductive material, and
wherein the first barrier layer and the second barrier layer include a same second conductive material.

12. The semiconductor device of claim 1, wherein upper surfaces of the first portions and upper surfaces of the second portions are exposed from the dielectric capacitor structure.

13. A semiconductor device, comprising:
a substrate including a first region and a second region surrounded by the first region;
a first interconnection structure on the first region of the substrate; and
a capacitor structure on the second region of the substrate,
wherein the capacitor structure includes
a first electrode structure including first portions spaced apart from each other in a first direction and extending in a second direction and a vertical direction,
a second electrode structure including second portions alternately arranged with the first portions in the first direction and extending in the second direction and the vertical direction, and
a dielectric capacitor structure between the first portions of the first electrode structure and the second portions of the second electrode structure, and
wherein the first interconnection structure includes
a first peripheral interconnection line extending in the second direction,
a first peripheral contact plug on the first peripheral interconnection line, and
a first peripheral dielectric structure on a side surface of the first peripheral interconnection line and a side surface of the first peripheral contact plug, and
wherein the first direction is parallel to an upper surface of the substrate, the second direction is parallel to the upper surface of the substrate and intersects the first direction, and the vertical direction is perpendicular to the upper surface of the substrate and intersects the first direction and the second direction,
wherein the first peripheral dielectric structure surrounds a side surface of the dielectric capacitor structure,
wherein the dielectric capacitor structure includes a first dielectric material having a first dielectric constant, and
wherein the first peripheral dielectric structure includes a second dielectric material having a second dielectric constant lower than the first dielectric constant.

14. The semiconductor device of claim 13,
wherein each of the first portions includes a first conductive layer and a first barrier layer covering a bottom surface and a side surface of the first conductive layer, and
wherein each of the second portions includes a second conductive layer and a second barrier layer covering a bottom surface and a side surface of the second conductive layer.

15. The semiconductor device of claim 13, wherein the first portions of the first electrode structure and the second portions of the second electrode structure have a plate shape.

16. The semiconductor device of claim 13, further comprising:
a first circuit element on the first region of the substrate;
a second circuit element on the second region of the substrate;
a first lower contact plug connected to the first circuit element;
a second lower contact plug connected to the second circuit element and having an upper surface coplanar with an upper surface of the first lower contact plug; and
a first insulating layer covering a side surface of the first lower contact plug and a side surface of the second lower contact plug,
wherein the capacitor structure is on the first insulating layer and connected to the first lower contact plug, and
the first peripheral interconnection line is on the first insulating layer and connected to the second lower contact plug.

17. The semiconductor device of claim 16, wherein the first insulating layer includes a third dielectric material having a third dielectric constant higher than the second dielectric constant of the first peripheral dielectric structure and less than the first dielectric constant of the dielectric capacitor structure.

18. The semiconductor device of claim 13, wherein the capacitor structure is spaced apart from the first interconnection structure in the first direction.

19. A semiconductor device, comprising:
a substrate;
a first circuit element on the substrate;
contact plugs connected to the first circuit element;
a first insulating layer on side surfaces of the contact plugs; and
a capacitor structure on the first insulating layer,
wherein the capacitor structure includes
a first electrode structure including first portions spaced apart from each other in a first direction parallel to an upper surface of the substrate and extending in a second direction intersecting the first direction, and extending in a vertical direction intersecting the first direction and the second direction,
a second electrode structure including second portions alternately arranged with the first portions in the first direction and extending in the second direction and in the vertical direction, and
a dielectric capacitor structure between the first portions of the first electrode structure and the second portions of the second electrode structure,
wherein the dielectric capacitor structure includes a first dielectric material having a first dielectric constant, and
wherein the first insulating layer includes a second dielectric material having a second dielectric constant lower than the first dielectric constant.

20. The semiconductor device of claim 19,
wherein the first circuit element includes a first gate structure and a first impurity region in the substrate on sides of the gate structure,
wherein the contact plugs include a first contact plug connected to the gate structure and a second contact plug connected to the first impurity region,
wherein the first contact plug is connected to one of the first portions, and
wherein the second contact plug is connected to one of the second portions.
